(19) United States
(12) Patent Application Publication
(10) Pub. No.: US 2024/0211651 A1
(43) Pub. Date: Jun. 27, 2024

(54) METHOD AND SYSTEM USING STOCHASTIC ASSESSMENTS FOR DETERMINING AUTOMATED DEVELOPMENT PLANNING

(71) Applicant: SAUDI ARABIAN OIL COMPANY, Dhahran (SA)

(72) Inventors: Mahesh Narayanan, Al Khobar (SA); Mehaboob Abdulaziz, Dhahran (SA); Khadija Bukhamsin, Dhahran (SA)

(73) Assignee: SAUDI ARABIAN OIL COMPANY, Dhahran (SA)

(21) Appl. No.: 18/537,249

(22) Filed: Dec. 12, 2023

Related U.S. Application Data
(60) Provisional application No. 63/476,510, filed on Dec. 21, 2022.

(51) Int. Cl. G06F 30/17

(52) U.S. Cl. CPC G06F 30/17; G06Q 50/02

(57) ABSTRACT

A method may include determining a first stochastic assessment for a geological region of interest based on first well data, mechanical failure data, and a stochastic model. The method may further include generating, automatically based on a screening criterion and the first stochastic assessment, a reservoir development plan for the geological region of interest. The method may further include determining a second stochastic assessment for the geological region of interest based on second well data and the stochastic model. The method may further include adjusting, automatically based on the screening criterion and the second stochastic assessment, the reservoir development plan to produce an adjusted reservoir development plan. The method may further include transmitting, to a control system coupled to a well, a command that implements a well operation in the adjusted reservoir development plan.

### CROSS-REFERENCE TO RELATED APPLICATIONS

This application claims priority to U.S. Provisional Patent Application Ser. No. 63/476,510, titled “METHOD AND SYSTEM USING STOCHASTIC ASSESSMENTS TO DETERMINE AUTOMATED DEVELOPMENT PLANNING,” which was filed on Dec. 21, 2022, and is incorporated herein by reference.

### BACKGROUND

Unconventional developments may be capital intensive requiring significant surface infrastructure and a high number of wells to achieve commercial volumes. For example, tight gas reservoirs categorized under the unconventional gas play umbrella may have low porosity and low to ultra-low permeability regions that may require hydraulic fracturing to produce particular levels of hydrocarbons. Such unconventional plays may exist in deep or shallow settings in varying pressure and temperature gradients and may be homogeneous or naturally fractured.

Developing an unconventional tight gas play with multiple structures and traps poses a multitude of challenges. Such reservoir developments may have varying economic value depending on the reservoir size, thickness, porosity, permeability, hydrocarbon fluid types, saturation, reservoir pressures and temperatures. The task before the sub-surface team is to steer and effectively focus exploration to unconventional plays with the highest value-added sequence of opportunities, e.g., to build a resilient reservoir development program. More specifically, one unconventional development may be selected over a different development based on a reduced amount of time necessary to move from hydrocarbon discovery to reservoir development (e.g., being able to fast track gas in a formation to gas in pipeline).

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method that includes obtaining first well data and mechanical failure data from various wells regarding a geological region of interest. The method further includes determining, by a computer processor, a first stochastic assessment for the geological region of interest based on the first well data, mechanical failure data, and a stochastic model. The method further includes generating, automatically by the computer processor and based on a screening criterion and the first stochastic assessment, a reservoir development plan for the geological region of interest. The reservoir development plan includes a first set of production wells based on a first set of well operations. The screening criterion removes at least one well operation from inclusion in the reservoir development plan. The method further includes obtaining second well data and second mechanical failure data from the wells. The method further includes determining, by the computer processor, a second stochastic assessment for the geological region of interest based on the second well data and the stochastic model. The method further includes adjusting, automatically by the computer processor and based on the screening criterion and the second stochastic assessment, the reservoir development plan to produce an adjusted reservoir development plan. The adjusted reservoir development plan includes a second set of production wells that is a subset of the first set of production wells based on a second set of well operations that is a subset of the first set of well operations. The method further includes transmitting, by the computer processor and to a control system coupled to a well, a command that implements a well operation among the second set of well operations in the adjusted reservoir development plan.

In general, in one aspect, embodiments relate to a system that includes a logging system coupled to a first well, a drilling system coupled to a second well, and a reservoir development manager that includes a computer processor. The reservoir development manager is coupled to the logging system and the drilling system. The reservoir simulator obtains, using at least in part the logging system, first well data from various wells regarding a geological region of interest. The wells include the first well. The reservoir simulator further obtains mechanical failure data from various drilling operations at the wells. The reservoir simulator further determines a first stochastic assessment for the geological region of interest based on the first well data, the mechanical failure data, and a stochastic model. The reservoir simulator further generates, automatically based on a screening criterion and the first stochastic assessment, a reservoir development plan for the geological region of interest. The reservoir development plan includes a first set of production wells based on a first set of well operations. The screening criterion removes at least one well operation from inclusion in the reservoir development plan. The reservoir simulator further obtains second well data and second mechanical failure data from the wells. The reservoir simulator further determines a second stochastic assessment for the geological region of interest based on the second well data and the stochastic model. The reservoir simulator further adjusts, automatically based on the screening criterion and the second stochastic assessment, the reservoir development plan to produce an adjusted reservoir development plan. The adjusted reservoir development plan includes a second set of production wells that is a subset of the first set of production wells based on a second set of well operations that is a subset of the first set of well operations. The reservoir simulator transmits, to the drilling system, a command that implements a drilling operation among the second set of well operations in the adjusted reservoir development plan.

In some embodiments, various hydraulic stimulation operations are determined for an unconventional reservoir based on well data and an adjusted reservoir development plan. Various well operations in the adjusted reservoir development plan may include the hydraulic stimulation operations. A hydraulic stimulation operation among hydraulic stimulation operations is performed using a stimulation control system and at a well. In some embodiments, historical scheduling data is obtained for various historical well operations. An amount of schedule variation may be determined for a predetermined well operation based on the historical scheduling data. A stochastic assessment may be based on the amount of schedule variation of the predetermined well operation. In some embodiments, a screening criterion corresponds to a predetermined threshold for a probability of commerciality. The screening criterion may remove a production well from among various production wells in a reservoir development plan. The removed production well may correspond to a predicted range of hydrocarbon production in the stochastic assessment that fails to satisfy the predetermined threshold.

In some embodiments, well data is obtained from various wells regarding a geological region of interest. A stochastic assessment is determined for various production wells in a reservoir development plan for the geological region of interest. A ranking criterion may be obtained for the reservoir development plan. A production well ranking may be determined of the production wells using the ranking criterion. The reservoir development plan may be determined based on the production well ranking. The reservoir development plan may describe a priority that the production wells are developed in the geological region of interest. In some embodiments, a ranking criterion corresponds to a probability that a predetermined amount of hydrocarbon that is produced by a respective production well exceeds a cost of developing the respective production well. A production well ranking may describe a predetermined order that various production wells are completed for developing a geological region of interest.

In some embodiments, a machine-learning model is obtained. Predicted cost data may be determined for a predetermined well operation determining using the machine-learning model and a portion of well data. A screening criterion may be a cost threshold. A predetermined well operation may be excluded from an adjusted reservoir development plan based on the predicted cost data failing to satisfy the cost threshold. In some embodiments, a stochastic assessment is determined using various Monte Carlo simulations. At least one Monte Carlo simulation among the Monte Carlo simulations may describe various probabilities for various well scenarios for at least one production well in a reservoir development plan. In some embodiments, a stochastic assessment includes a first amount of uncertainty at a well's exploratory stage, a second amount of uncertainty at a well's appraisal stage, a third amount of uncertainty at a well's pilot stage, and/or a fourth amount of uncertainty at a well's production stage.

In some embodiments, historical cost data is obtained for various historical well operations. An amount of cost variation of various well operations may be determined based on the historical cost data. A stochastic assessment may be based on the amount of cost variation. In some embodiments, a command is transmitted to a drilling system at a well and based on adjusted reservoir development plan. Various production wells in the adjusted reservoir development plan may include the well with the drilling system. The drilling system may include a control system coupled to a drill string and a drill bit. The drilling system may perform a drilling operation that produces a well path through a geological region of interest in response to receiving the second command. In some embodiments, an adjusted reservoir development plan among various reservoir development plans is presented by a user device using a graphical user interface. A user selection of the adjusted reservoir development plan may be obtained in response to a user input within the graphical user interface. A command may be transmitted in response to the user selection. In some embodiments, a well operation in a reservoir development plan is selected from an injection operation using an injection well, a drilling operation for a well path for a production well, a hydraulic stimulation operation for the production well, a well completion operation for the production well, a well intervention operation for the production well, and/or a well maintenance operation for the production well.

In some embodiments, a downhole sampling device is coupled to a well. The downhole sampling device may acquire a downhole fluid sample from a wellbore coupled to the well. The downhole sampling device may include a hydraulic fluid chamber, a sample chamber, a floating piston, a mechanical timer, a triggering system, a hanging head, and a closing mechanism. Well data may be based on the downhole fluid sample.

In light of the structure and functions described above, embodiments of the invention may include respective means adapted to carry out various steps and functions defined above in accordance with one or more aspects and any one of the embodiments of one or more aspect described herein.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1, 2, 3A, and 3B show systems in accordance with one or more embodiments.

FIG. 4A and 4B show flowcharts in accordance with one or more embodiments.

FIGS. 5A, 5B, 5C, 5D, 5E, 5F, 5G, 5H, 5I, and 5J show examples in accordance with one or more embodiments.

FIG. 6 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.)

may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include systems and methods that use various stochastic assessments to perform project screening and/or ranking of possible projects within a reservoir development plan. For example, a reservoir development plan may include exploratory operations (e.g., seismic surveys and exploratory pilot wells), well operations (e.g., drilling production wells and injection wells as well as performing various well completions), and ongoing maintenance and operation of wells for developing a reservoir region. For example, a reservoir development plan may correspond to a sequence of projects performed in a particular order for implementing an unconventional tight gas play. A reservoir development plan may be implemented as a stage gate decision tree, where outcomes of different stages may be analyzed as a series of staged decisions. A particular stage in a reservoir development plan may have a decision review point, development targets, and various reservoir metric thresholds that can affect latter projects in the sequence.

Moreover, reservoir development plans may be determined and/or adjusted using one or more stochastic assessments. A stochastic assessment may describe a probability distribution of various outcomes associated with different projects within a reservoir development plan. At a particular stage, multiple realizations of possible outcomes may be determined to calculate probability weighted outcomes through various stochastic assessments that describe stage results as a probability distribution. In some embodiments, for example, an automated stochastic workflow uses different types of well data (e.g., well sub-surface data and well surface data) and various commercial risks (e.g., cost data and expected productivity data for future hydrocarbon production) for screening and ranking of competing projects within one or more reservoir development plans. In particular, different reservoir development plans may have different stochastic assessments based on different uncertainties determined using one or more stochastic models. Examples of data inputs for stochastic models may include well data (such as surface and sub-surface well data), reservoir development data, drilling cost data, well completion cost data, well maintenance and operation cost data, geological failure data of various wells, and/or the mechanical failure data of various well operations.

In some embodiments, an automated stochastic workflow may address in real-time technical and commercial uncertainties with a particular stochastic model. For example, a stochastic model may include a Monte-Carlo model that predicts a range of possible reservoir development outcomes using various analytical tools. Various stochastic models may have different distribution types and different ranges for data variables. Using a structured stochastic approach, different combination of data inputs may be used to determine outcomes of various unconventional reservoir developments under consideration. For example, data inputs may be sampled using a Monte Carlo simulation in order to generate a multitude of trials. In some embodiments, different screening criteria and/or ranking criteria are used to analyze various stochastic assessments. For example, different criteria may assist decision makers in making informed reservoir development decisions in support of a particular reservoir strategy. Examples of screening criteria and/or ranking criteria include probability of commerciality (Pc), expected monetary value (EMV) and peak funding exposure. Thus, screening and ranking of reservoir opportunities may be based on project value and a user's strategy. screening criteria may identify those projects which meet or exceed a predetermined threshold, whereas ranking criteria may order those projects from most desirable outcome to least desirable outcome. A screening criterion may be used to ensure only those reservoir development plans are implemented which are likely to contribute to achieving various user objectives. Likewise, screening criteria and/or ranking criteria may be used to analyze the range of uncertainty and risk at multiple stages (e.g., exploratory stage, appraisal stage, pilot stage, production stage, etc.) of a reservoir development plan.

In contrast to a deterministic approach, stochastic assessments may provide an understanding of the range of possible outcomes at a particular stage to enable effective decision making. An automated stochastic approach may integrate various key variables, probability distributions, random variable functions and multiple realizations combined with implementation across a well management network that operates multiple control systems at different well sites and other reservoir locations.

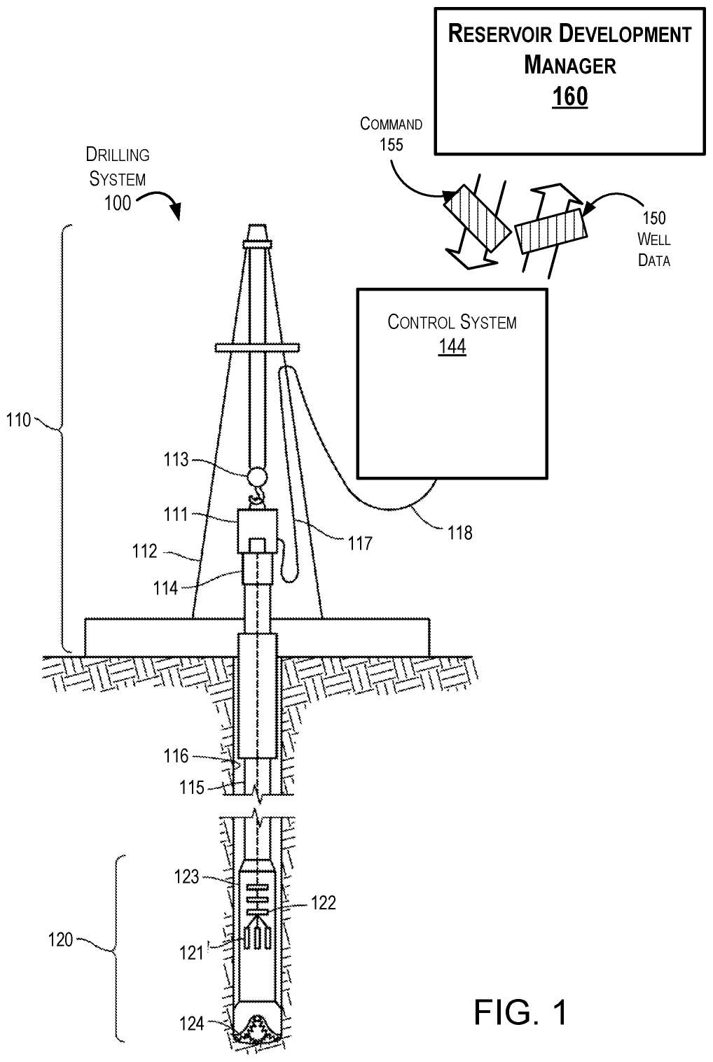

Turning to FIG. 1, FIG. 1 shows a drilling system (100) that may include a top drive drill rig (110) arranged around the setup of a drill bit logging tool (120). A top drive drill rig (110) may include a top drive (111) that may be suspended in a derrick (112) by a travelling block (113). In the center of the top drive (111), a drive shaft (114) may be coupled to a top pipe of a drill string (115), for example, by threads. The top drive (111) may rotate the drive shaft (114), so that the drill string (115) and a drill bit logging tool (120) cut the rock at the bottom of a wellbore (116). A power cable (117) supplying electric power to the top drive (111) may be protected inside one or more service loops (118) coupled to a control system (144). As such, drilling mud may be pumped into the wellbore (116) through a mud line, the drive shaft (114), and/or the drill string (115).

The control system (144) may include one or more programmable logic controllers (PLCs) that include hardware and/or software with functionality to control one or more processes performed by the drilling system (100). Specifically, a programmable logic controller may control valve states, fluid levels, pipe pressures, warning alarms, and/or pressure releases throughout a drilling rig. In particular, a programmable logic controller may be a ruggedized computer system with functionality to withstand vibrations, extreme temperatures, wet conditions, and/or dusty conditions, for example, around a drilling rig. Without loss of generality, the term “control system” may refer to a drilling operation control system that is used to operate and control the equipment, a drilling data acquisition and monitoring system that is used to acquire drilling process and equipment data and to monitor the operation of the drilling process, or a drilling interpretation software system that is used to analyze and understand drilling events and progress. For example, the control system (144) may be coupled to the sensor assembly (123) in order to perform various program functions for up-down steering and left-right steering of the drill bit (124) through the wellbore (116). While one control system is shown in FIG. 1, the drilling system (100) may include multiple control systems for managing various well drilling operations, maintenance operations, well completion operations, and/or well intervention operations.

The wellbore (116) may include a bored hole that extends from the surface into a target zone of the hydrocarbon-bearing formation, such as the reservoir. An upper end of the wellbore (116), terminating at or near the surface, may be referred to as the “up-hole” end of the wellbore (116), and a lower end of the wellbore, terminating in the hydrocarbon-bearing formation, may be referred to as the “down-hole” end of the wellbore (116). The wellbore (116) may facilitate the circulation of drilling fluids during well drilling operations, the flow of hydrocarbon production (“production”) (e.g., oil and gas) from the reservoir to the surface during production operations, the injection of substances (e.g., water) into the hydrocarbon-bearing formation or the reservoir during injection operations, or the communication of monitoring devices (e.g., logging tools) into the hydrocarbon-bearing formation or the reservoir during monitoring operations (e.g., during in situ logging operations).

As further shown in FIG. 1, sensors (121) may be included in a sensor assembly (123), which is positioned adjacent to a drill bit (124) and coupled to the drill string (115). Sensors (121) may also be coupled to a sensor assembly (123) that includes a processor, memory, and an analog-to-digital converter (122) for processing sensor measurements. For example, the sensors (121) may include acoustic sensors, such as accelerometers, measurement microphones, contact microphones, and hydrophones. Likewise, the sensors (121) may include other types of sensors, such as transmitters and receivers to measure resistivity, gamma ray detectors, etc. The sensors (121) may include hardware and/or software for generating different types of well logs (such as acoustic logs or sonic longs) that may provide well data about a wellbore, including porosity of wellbore sections, gas saturation, bed boundaries in a geologic formation, fractures in the wellbore or completion cement, and many other pieces of information about a formation. If such well data is acquired during well drilling operations (i.e., logging-while-drilling), then the information may be used to make adjustments to drilling operations in real-time. Such adjustments may include rate of penetration (ROP), drilling direction, altering mud weight, and many others drilling parameters.

In some embodiments, acoustic sensors may be installed in a drilling fluid circulation system of a drilling system (100) to record acoustic drilling signals in real-time. Drilling acoustic signals may transmit through the drilling fluid to be recorded by the acoustic sensors located in the drilling fluid circulation system. The recorded drilling acoustic signals may be processed and analyzed to determine well data, such as lithological and petrophysical properties of the rock formation. This well data may be used in various applications, such as steering a drill bit using geosteering, casing shoe positioning, etc.

Keeping with FIG. 1, when completing a well, one or more well completion operations may be performed prior to delivering the well to the party responsible for production or injection. Well completion operations may include casing operations, cementing operations, perforating the well, gravel packing, directional drilling, hydraulic and acid stimulation of a reservoir region, and/or installing a production tree or wellhead assembly at the wellbore (116). Likewise, well operations may include open-hole completions or cased-hole completions. For example, an open-hole completion may refer to a well that is drilled to the top of the hydrocarbon reservoir. Thus, the well is cased at the top of the reservoir, and left open at the bottom of a wellbore. In contrast, cased-hole completions may include running casing into a reservoir region. Cased-hole completions are discussed further below with respect to perforation operations.

In one well delivery example, the sides of the wellbore (116) may require support, and thus casing may be inserted into the wellbore (116) to provide such support. After a well has been drilled, casing may ensure that the wellbore (116) does not close in upon itself, while also protecting the wellstream from outside incumbents, like water or sand. Likewise, if the formation is firm, casing may include a solid string of steel pipe that is run on the well and will remain that way during the life of the well. In some embodiments, the casing includes a wire screen liner that blocks loose sand from entering the wellbore (116).

In another well delivery example, a space between the casing and the untreated sides of the wellbore (116) may be cemented to hold a casing in place. This well operation may include pumping cement slurry into the wellbore (116) to displace existing drilling fluid and fill in this space between the casing and the untreated sides of the wellbore (116). Cement slurry may include a mixture of various additives and cement. After the cement slurry is left to harden, cement may seal the wellbore (116) from non-hydrocarbons that attempt to enter the wellstream. In some embodiments, the cement slurry is forced through a lower end of the casing and into an annulus between the casing and a wall of the wellbore (116). More specifically, a cementing plug may be used for pushing the cement slurry from the casing. For example, the cementing plug may be a rubber plug used to separate cement slurry from other fluids, reducing contamination and maintaining predictable slurry performance. A displacement fluid, such as water, or an appropriately weighted drilling fluid, may be pumped into the casing above the cementing plug. This displacement fluid may be pressurized fluid that serves to urge the cementing plug downward through the casing to extrude the cement from the casing outlet and back up into the annulus.

Keeping with well operations, some embodiments include perforation operations. More specifically, a perforation operation may include perforating casing and cement at different locations in the wellbore (116) to enable hydrocarbons to enter a wellstream from the resulting holes. For example, some perforation operations include using a perforation gun at different reservoir levels to produce holed sections through the casing, cement, and sides of the wellbore (116). Hydrocarbons may then enter the wellstream through these holed sections. In some embodiments, perforation operations are performed using discharging jets or shaped explosive charges to penetrate the casing around the wellbore (116).

In another well delivery, a filtration system may be installed in the wellbore (116) in order to prevent sand and other debris from entering the wellstream. For example, a gravel packing operation may be performed using a gravel-packing slurry of appropriately sized pieces of coarse sand or gravel. As such, the gravel-packing slurry may be pumped into the wellbore (116) between a casing's slotted liner and the sides of the wellbore (116). The slotted liner and the gravel pack may filter sand and other debris that might have otherwise entered the wellstream with hydrocarbons.

In another well delivery, a wellhead assembly may be installed on the wellhead of the wellbore (116). A wellhead assembly may be a production tree (also called a Christmas tree) that includes valves, gauges, and other components to provide surface control of subsurface conditions of a well.

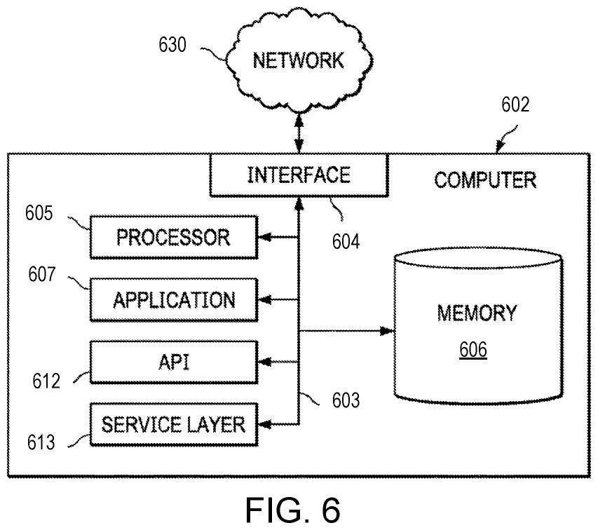

In some embodiments, a reservoir development manager (160) is coupled to one or more control systems (e.g., control system (144)) at a wellsite. For example, a reservoir development manager (160) may include hardware and/or software to collect well operation data (e.g., well operation data (150)) from one or more well sites. Likewise, the reservoir development manager (160) may monitor various well operations performed by various service entities. In some embodiments, a reservoir development manager (160) is a controller located on a server remote from the well site. In some embodiments, a reservoir development manager (160) may be similar to a control system coupled to the drilling system (100). In some embodiments, the reservoir development manager (160) may include a computer system that is similar to the computer system (602) described below with regard to FIG. 6 and the accompanying description.

In some embodiments, for example, a well operation may include various logistical considerations based on issues such as service providers and material availability, nearby activities in surrounding wells, tool availability, weather conditions, safety concerns, etc., as well as various service provider considerations (e.g., local contract conditions, the scope of the sub-tasks within the contracts, operational aspects, involved parties, interdepartmental interactions, etc.). As such, human site planning may be a tedious process that is difficult to re-schedule based on changing well scenarios. Likewise, human planners may miss important screening criteria for avoiding conflicts and human errors. Accordingly, some embodiments include a reservoir development manager that may be a “smart system” or “expert system” that automatically plans, synchronizes, and/or readjusts a reservoir development plan (e.g., reservoir development plans X (269)) for one or more well operations for developing a reservoir region. In other words, a reservoir development manager may be an artificial intelligence entity operation on a well management network (e.g., as a network controller) that performs such functionality.

Moreover, some embodiments include a reservoir development manager with self-decision functionality that operates independently and with flexibility. For example, the reservoir development manager may perform a learning process that detects unusual items not involved for planning purposes (e.g., planning exploration, drilling, completions, well interventions, etc., for a particular reservoir region). For example, a reservoir development manager may determine statistical trends based on well data (such as sub-surface data, maintenance costs, and service log data), geological data, and/or service provider data. Likewise, a reservoir development manager may determine one or more additional values or weights for arranging the setup of well sites schedules. This flexibility may accommodate changes in real time and on the fly observed matters, like safety concerns, risk factors, alternate logistics interactions (other service entities, like government factors, weather factors, safety factors, legal factors, etc.) which builds trends and improve robustness of various reservoir development plans by advising about possible issues. These different factors may provide the data inputs that are adjusted over time to optimize a particular screening criterion.

Furthermore, some embodiments use one or more machine learning algorithms to determine which data inputs to use for a stochastic assessment. For example, different sets of data inputs may maximize operational efficiency and hydrocarbon production at one or more wells, while also minimizing operational costs for those same wells. For example, an optimized set of data inputs may be a subset of larger aggregated set of data inputs identified over a well management network. These aggregated data inputs may be recognized by a reservoir development manager, where the reservoir development manager proscribes different weights or significances to various data inputs. Thus, a reservoir development manager may provide a flexible method to accommodate multiple screening criteria (e.g., screening criteria X (261)) and/or ranking criteria (e.g., ranking criteria X (262)) for swapping importance/relevance of different data inputs that corresponds to various incidents, costs, contracts, performances, etc.). Thus, a reservoir development plan may be analyzed in real-time to adjust one or more well operations within the particular reservoir development plan accordingly. Thus, a reservoir development manager may automatically readjust variables for a reservoir development plan based on predicting their future importance to a user. In some embodiments, a reservoir development plan may be updated based on real-time observed matters during actual performance of the reservoir development plan (e.g., in response to changing safety concerns, alternate logistics interaction, contract terms, conditions, scope, cost and resources related to implementation of the plan, etc.).

In some embodiments, well intervention operations may include various operations carried out by one or more service entities for an oil or gas well during its productive life (e.g., fracking operations, CT, flow back, separator, pumping, wellhead and Christmas tree maintenance, slickline, wireline, well maintenance, stimulation, braded line, coiled tubing, snubbing, workover, subsea well intervention, etc.). For example, well intervention activities may be similar to well completion operations, well delivery operations, and/or drilling operations in order to modify the state of a well or well geometry. In some embodiments, well intervention operations provide well diagnostics, and/or manage the production of the well. With respect to service entities, a service entity may be a company or other actor that performs one or more types of oil field services, such as well operations, at a well site. For example, one or more service entities may be responsible for performing a cementing operation in the wellbore (116) prior to delivering the well to a producing entity.

Moreover, a reservoir development manager (160) may include functionality for coordinating various oilfield services, such as exploratory operations, pilot well operations, drilling operations, and well completion operations using various commands (e.g., command (155), command Y (295)), e.g., by transmitting commands to various network devices (e.g., control system (144)) in a drilling system as well as various user devices at the well site. In some embodiments, for example, a command is a network message that automatically assigns or reassigns tasks or operations to various service entities at a well site. For example, a reservoir development manager (160) may communicate with one or more service entities through various user devices, e.g., by receiving periodic status reports, sending messages through user interfaces, etc. Likewise, the reservoir development manager (160) may also collect other well operation data, such as sensor data from the drilling system (100), service provider data, resource data (including rig and rigless site daily reports), feedback through a human machine interface from other personnel at the well site, and/or data from a historian operating at the well site. The reservoir development manager (160) may be a computer system similar to computer system (602) described below in FIG. 6 and the accompanying description.

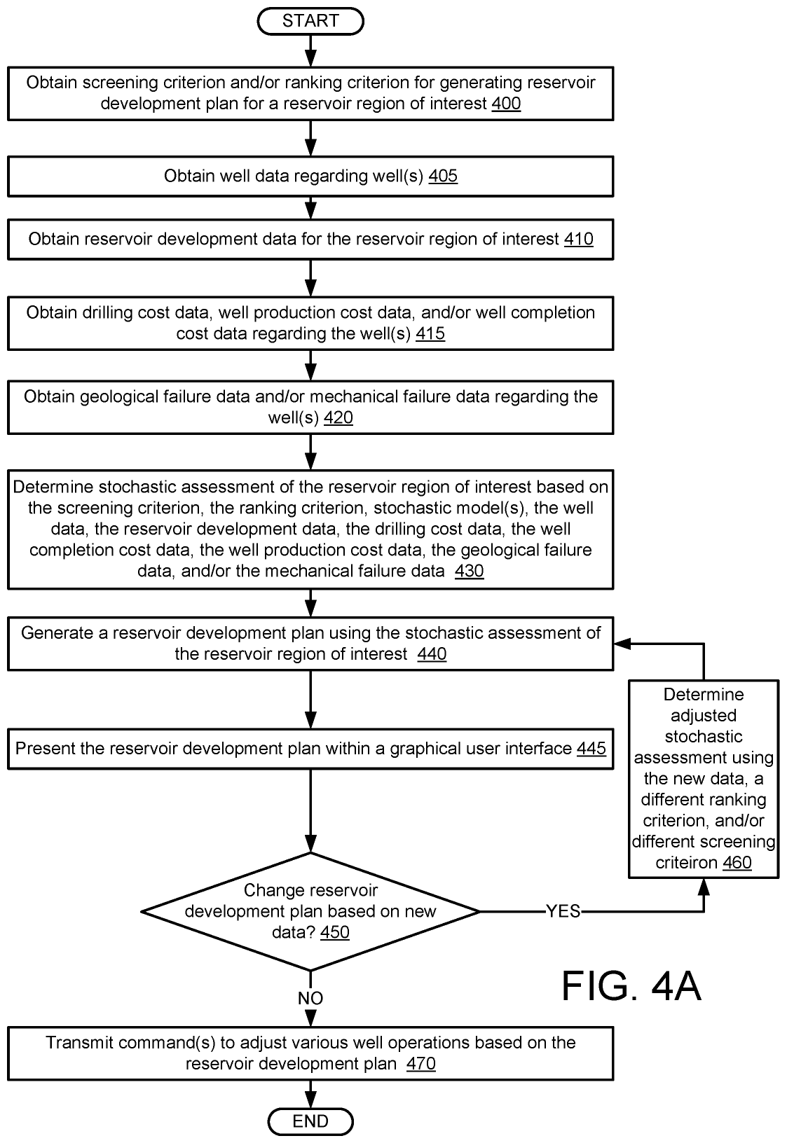

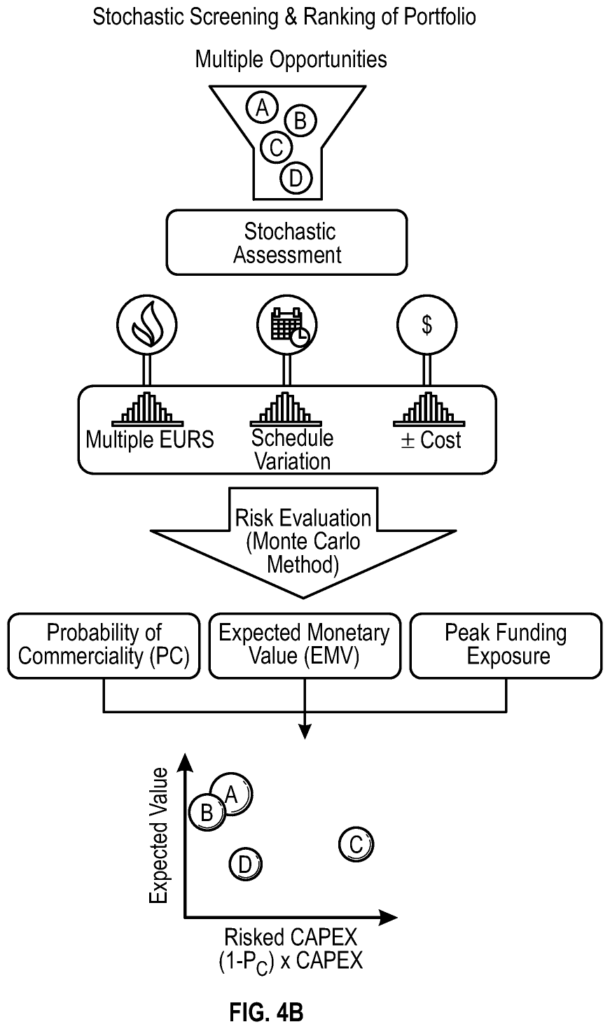

In some embodiments, a reservoir development manager (160) includes one or more machine-learning models for determining a reservoir development plan using data inputs. For example, a screening criterion may correspond to a specific set of data inputs that may be adjusted (e.g., data inputs added and/or removed) to determine the viability of one or more projects in a reservoir development plan. For example, artificial intelligence (AI) techniques may assist a reservoir development manager in linking contributions of different service entities to a well delivery process (i.e., a well delivery process that includes one or more well operations) to evaluate efficiency and service quality. In some embodiments, for example, a reservoir development manager (160) uses a ML model to determine a reservoir development plan for measuring a service entity's contribution to a particular well intervention. For more information regarding reservoir development planning, see FIGS. 4A and 4B below and the accompanying description.

In some embodiments, production wells and/or injection wells are used in one or more stimulation operations. For example, one type of stimulation operation is a water-alternating-gas (WAG) operation. A WAG operation may be a cyclic process of injecting water followed by gas. Using a WAG injection, macroscopic or microscopic sweep efficiency may be improved for a reservoir, e.g., by maintaining nearly initial high pressure, slow down any gas breakthroughs, and reduce oil viscosity. Likewise, WAG injections may also decrease residual oil saturation resulting from three phase flows and effects associated with relative permeability hysteresis. Thus, some stimulation operations may produce gas flooding, which is a type of enhanced oil recovery (EOR) method for increasing recovery of light to moderate oil reservoirs. In some stimulation operations, water may be injected during the initial phase of the operation and followed by a gas (e.g., carbon dioxide) because water may have a higher mobility ratio than the injected gas, thereby preventing breakthroughs in the reservoir. Injected gas may be a mixture of hydrocarbon gas or nonhydrocarbon gases. With hydrocarbon gases, the gas mixture may include methane, ethane, and propane for achieving a miscible or immiscible gas-oil system in the reservoir. With nonhydrocarbon gases, the gas mixture may include carbon dioxide (CO₂), nitrogen (N₂), and some exotic gases that displace fluid in the reservoir. Likewise, gas may also be injected directly into a reservoir, e.g., into the gas cap, to compensate for the reservoir's pressure decline.

Furthermore, a stimulation injection during a stimulation operation may correspond to various injection parameters, such as bank size, cycle time, and a predetermined water-gas ratio (also called a “WAG ratio”). Bank size may refer to a size of sequential banks of fluids (e.g., oil, CO₂ and water) formed in the reservoir rock in response to a stimulation operation that migrate from the injection to the production wells. For illustration, a WAG ratio of 1:1 may result in a high oil production for one or more production wells, such as production wells coupled to a miscible reservoir. Based on some reservoir parameters such as oil composition, gas flooding can be carried out in miscible or immiscible conditions. Moreover, different types of stimulation operations may use different stimulation parameters. Examples of different stimulation operations may include: (1) continuous gas injections; (2) WAG injections; (3) simultaneous water-alternating-gas (SWAG) injections; and (4) tapered WAG injections. Different strategies have been developed by the petroleum industry to cope with these conditions.

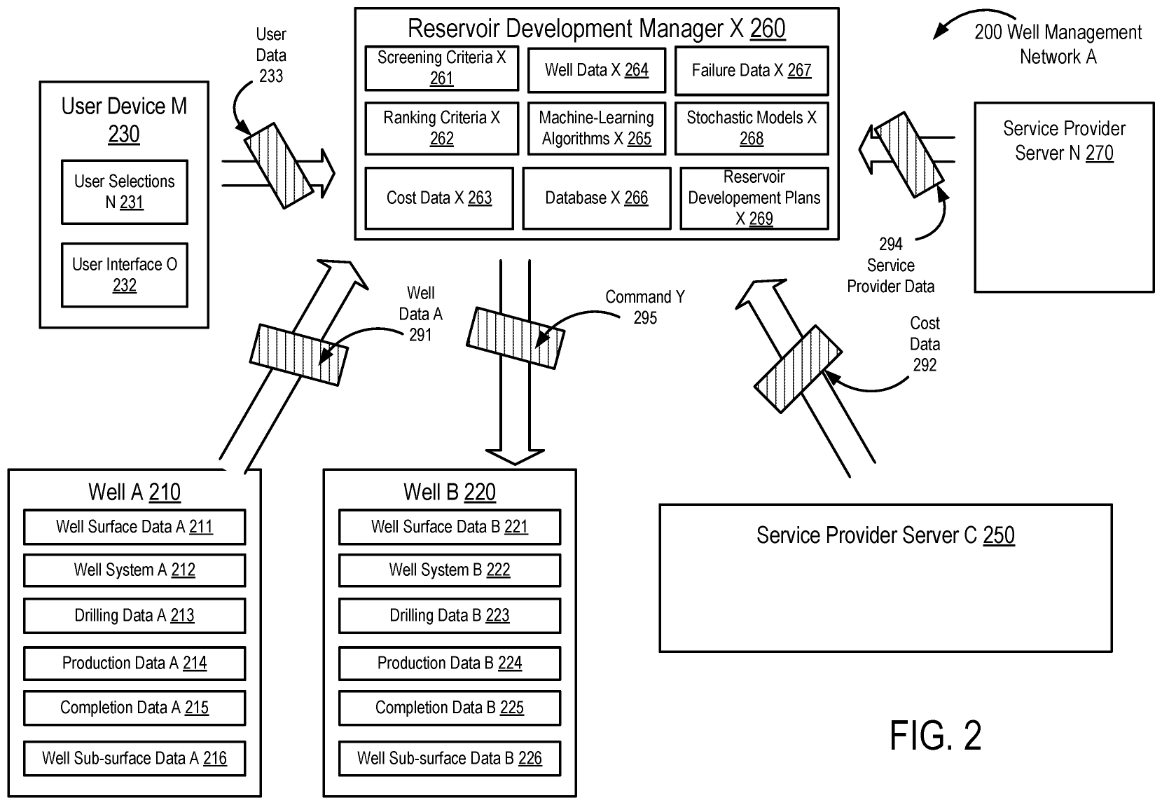

Turning to FIG. 2, FIG. 2 shows a schematic diagram in accordance with one or more embodiments. As shown in FIG. 2, a well management network (e.g., well management network A (200)) may include a reservoir development manager (e.g., reservoir development manager X (260)), various oil and gas wells (e.g., well A (210), well B (220)), various servers (e.g., service provider server N (270), service provider server C (250)), and various user devices (e.g., user device M (230)), and/or various network elements (not shown). A well (e.g., well A (210), well B (220)) may include a well system (e.g., well system A (212), well system

B (222)) that is similar to well system (100) described above in FIG. 1 and the accompanying description. In some embodiments, various types of well data (e.g., well data X (264), well sub-surface data A (216), well sub-surface data B (226), well data A (291)) are collected over the well management network, such as well surface data (well surface data A (211), well surface data B (221)), well sub-surface data (well sub-surface data A (216), well sub-surface data B (226)). For example, well sub-surface data may include downhole pressure and temperature measurements acquired by downhole sensors. On the other hand, well surface data may include wellhead temperature and pressure data. The well management network may also collect production data (e.g., production data A (214), production data B (224)), drilling data (e.g., drilling data A (213), drilling data B (223)), completion data (e.g., completion data A (215), completion data B (225)), and failure data (e.g., failure data X (267)), such as geological failure data and/or mechanical failure data. Production data may include total flow rate data, water cut data, and gas-oil ratio data. Drilling data may include information regarding well paths, rate of penetration data, weight-on-bit data, etc. Completion data may include hydraulic fracturing data, data for other types of stimulation operations, etc. Likewise, the well management network may also collect data from users and entities responsible for implementing and performing well operations (e.g., user data (233), cost data (292), service provider data (294)) from one or more user devices and/or data servers (e.g., user device M (230), service provider server C (250), well service provider server N (270)). Cost data may include information describing material costs, tools costs, hourly wages for oilfield workers, etc. Service provider data may include oilfield services availability, time required to perform various well operations, etc.

In some embodiments, a reservoir development manager performs one or more stochastic assessments using based on various data inputs and one or more stochastic models (e.g., stochastic models X (268)). Likewise, a stochastic assessment may be analyzed using a screening criterion (e.g., one of screening criteria X (261)) and/or a ranking criterion (e.g., one of ranking criteria X (262)).

In some embodiments, a service provider server may be a remote server that includes hardware and/or software with functionality for managing and/or tracking equipment. For example, a service provider server may maintain resource data on drilling tools and various well operation equipment based on the location of a respective tool for a particular time period. Likewise, a remote server may be a server that communicates to various well sites over the Internet or through a cloud computing environment. When tools are committed to various well operations, the current or future operation with the respective tool may be logged automatically with the service provider server (e.g., by detecting a scan of the tool's unique identifier). Accordingly, a service provider server may transmit resource data (e.g., updates to changes in a respective tool's cost for a particular well site) to a reservoir development manager.

In some embodiments, the reservoir development manager (e.g., reservoir development manager X (260)) may include hardware and/or software that obtains a screening criterion (e.g., one of screening criteria X (261)) and/or a ranking criterion (e.g., one of ranking criteria X (262)) regarding reservoir development activities, well data (e.g., well data X (263)), and/or service provider data (e.g., service provider data (294)) from data inputs (e.g., user data (233), well data A (291), service provider data (294)). For example, the reservoir development manager (e.g., reservoir development manager X (260)) may acquire the screening criterion (e.g., screening criteria X (261)) from a user data (233) collected by a user device (e.g., user device M (230)). The user device (e.g., user device M (230)) may include hardware and/or software to receive real-time user selections (e.g., user selections N (231)) by interacting with a user via a user interface (e.g., user interface O (232)). Specifically, the reservoir development manager (e.g., reservoir development manager X (260)) allows the user to interact with the user device (e.g., user device M (230)) to verify the actual reservoir development plan setup is as per desire and monitor the performance as the self-learning process of the ML algorithm is set up for retro alimentation up on the actual events. When the reservoir development plan setup is not desired, the user can modify the user selections (e.g., user selections N (231)) to adjust the screening criterion via the graphical display (e.g., user interface O (232)).

Keeping with FIG. 2, in some embodiments, the reservoir development manager (e.g., reservoir development manager X (260)) may include hardware and/or software to generate one or more reservoir development plans within the well management network (e.g., well management network A (200)) using one or more ML algorithms (e.g., ML algorithms X (265)) based on the obtained screening criterion and reservoir development activities, such as drilling exploratory wells, performing stimulation operations of future production wells, etc. For example, a reservoir development manager may implement machine learning by gathering data from actual well progress data (e.g., status updates at a well site regarding one or more well operations) and real events to tune a particular screening criterion and/or logical margins regarding flexibility for a well site's year, monthly, weekly plans. Thus, different inputs (e.g., types of data or different data sources) may provide the initial setup of a particular screening criterion, where the data inputs may be customized according to different well scenarios to better arrange a forward schedule for a reservoir development plan. Since the reservoir development manager is self-maintained on data storage and usage for retro alimentation, the reservoir development manager may require minimal supervision of human interaction. In some embodiments, the reservoir development manager advises a user about a plan's regular structure of setting a reservoir development plan when the learning process detects possible related concerns that a human might miss due to the amount of variables and possible related issues. For example, an advisement may be a message prompt in a graphical user interface managed by the reservoir development manager.

In some embodiments, for example, the reservoir development manager (e.g., reservoir development manager X (260)) applies one or more ML algorithms (e.g., an unsupervised ML algorithm, a reinforcement ML algorithm, a self-supervised ML algorithm, etc.) to train a model. Specifically, the reservoir development manager (e.g., reservoir development manager X (260)) applies the model to generate a reservoir development plan at a well site using data inputs regarding one or more well intervention providers and one or more well conditions.

With respect to ML models, different types of ML models may be used, such as convolutional neural networks, deep neural networks, recurrent neural networks, support vector machines, decision trees, inductive learning models, deductive learning models, unsupervised learning models, supervised learning models, reinforcement learning models, self-supervised learning models, etc. In some embodiments, a reservoir development manager may generate augmented or synthetic data to produce a large amount of interpreted data for training a particular model. Likewise, a ML model may be trained using one or more ML algorithms. For example, a backpropagation algorithm may be used to train a neural network. The training data may include the predetermined screening criterion and data inputs from historical events regarding one or more well intervention providers and one or more well conditions. A reservoir development manager may continue to train the ML model by a self-feeding database (e.g., database X (266)) for historical learning process. Thus, the ML model predicts the reservoir development plan for performance as the self-learning process of the algorithm is setup for retro alimentation upon the actual events as desired.

With respect to neural networks, for example, a neural network may include one or more hidden layers, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning, a neural network may determine which data inputs should receive greater priority in determining one or more specified outputs of the neural network. Likewise, these weighted data inputs may be summed such that this sum is communicated through a neuron's activation function to other hidden layers within the neural network. As such, the activation function may determine whether and to what extent an output of a neuron progresses to other neurons where the output may be weighted again for use as an input to the next hidden layer.

In some embodiments, a reservoir development manager is used to generate a reservoir development plan within a well management network for planning, synchronizing and optimizing the logistics of a reservoir development plan using one or more ML algorithms (e.g., an unsupervised ML algorithm, a reinforcement ML algorithm, a self-supervised ML algorithm) to maximize operational efficiency, availing hydrocarbon and minimizing budget expenditure. In some embodiments, a first reservoir development plan may be generated by the reservoir development manager based on a predetermined screening criterion or ranking criterion determined by a user based on real-time observed matters (e.g., changes in costs and economics of hydrocarbon production, changes to sub-surface data within a reservoir region, etc.). The reservoir development manager may apply one or more ML algorithms to adjust the reservoir development plan based on new data.

Furthermore, the reservoir development manager may apply one or more ML algorithms to generate multiple reservoir development plans for different well scenarios for a well site of interest by using real-time well data. Accordingly, a reservoir development manager may have the capability to adapt to different logistics conditions and schemes. In some embodiments, the adjusted reservoir development plan is outputted for display for a user via a graphical user interface for a user to observe appearances, conflicts, and awareness of possible issues with the plan. For example, the reservoir development manager may automatically self-feed and build a database for a historical learning process that clearly enumerates changes to a reservoir development plan based on newly acquired data and statistical trends.

In some embodiments, the reservoir development manager may perform an unsupervised ML algorithm to train a model for performing a stochastic assessment. In particular, unsupervised learning requires only unlabeled data to build a compact internal representation to formulate a pattern learning task for the data inputs. The objective of an unsupervised learning algorithm may force the neural network to learn the compact internal representation (e.g., natural clusters) of data inputs based on multiple attributes to solve the task of interest. For example, an unsupervised learning algorithm may build a reservoir development plan and classifies the pattern of reservoir development activities based on various data inputs.

In some embodiments, oilfield activity planning is a very demanding task and requires inputs from various sources. Some input sources may include reservoir requirements, hydrocarbon production requirements, maintenance and servicing requirements, and field implementation outputs. These input sources may depend on secondary inputs that are dynamic in nature. For example, various reservoir requirements may depend on several data inputs such as hydrocarbon demand, drilling requirements, production enhancement requirements, reservoir changes, and tie-in requirements. As such, reservoir requirements may be used to forecast a required hydrocarbon production based on global demands (e.g., for planning the number of new wells needed to be drilled to meet the required hydrocarbon production). Likewise, reservoir requirements may change the reservoir targets on existing wells to meet new or different production targets. In addition, reservoir requirements may forecast tie-in plans to connect certain wells to hydrocarbon production facilities. Similarly, production requirements may depend on hydrocarbon demand in terms of particular types and qualities, such as crude oil grade, sweet or sour natural gas, etc. Other data inputs may arise from the need to maintain hydrocarbon production capacity from one or more existing wells. Example of such data inputs may include stimulation or performing scale removal to restore well productivity at one or more wells. In addition, some scheduling requirements may arise from the status of the hydrocarbon processing facilities. For example, some well activities and well tasks may be unable to be performed if the hydrocarbon processing facility is not operational (e.g., a processing plant is shut down for maintenance and inspection, or an emergency situation occurs). In contrast, other tasks may be performed while the processing facility is shut down. A reservoir development manager may use these different data sources to adjust one or more reservoir development plans. Moreover, production requirement inputs may be based on monitoring and acquiring well data, field data, and reservoir data through various surveillance activities such as well corrosion monitoring and acquiring static bottom hole pressure, etc.

With regard to the maintenance and servicing requirements, several inputs may be used, such as performing maintenance on the well through rig workover. Thus, workover operations may be performed to replace corroded tubings, or repairing tubing annulus communication for example. Other data inputs may include surveillance, inspection, testing and sampling such as annuli survey, landing base inspection, wellhead valve integrity tests, and surface sampling of reservoir fluids such as water sampling. In addition, wells servicing may be required such as wellhead valves cycling and greasing and wellhead repairs. Also, in emergency situations, wells may need to be attended to control the emergency situation (e.g., by shutting the well or installing an isolation plugs). In case of an emergency, a reservoir development manager may identify all the affected wells faster in order to be shut-in and control the emergency situation.

Based on the acquired data inputs, a reservoir development manager may generate one or more plans and task schedules. In some embodiments, a reservoir development manager estimates required budgets as well as time and resources to perform various tasks in addition to estimating hydrocarbon gains. Thus, a reservoir development manager may also provide feedback and/or recommendations or suggested changes to the different input sources to meet various constraints such as available resources and allocated budgets. Once reservoir development plan is approved and executed, the reservoir development manager may collect the input information from the different sources such as rig and workover operations details, rigless operations details, maintenance and servicing details, tie-in details, surveillance outputs, and sampling output. Those data sources may generate information such as the rig and rigless site reports, stimulation job reports, maintenance reports, and logging output. Data input sources may also form the feedline to provide the data needed for a machine learning process, where a system may utilize machine-learning algorithms (e.g., machine-learning algorithms X (265)) to read and compare acquired data with a particular plan. Thus, a system may identify changes that occurred during an implementation phase (e.g., problems and contingencies that arose, changes in field and reservoirs' conditions, etc.). Some processes may be thus repeated in a different plan, while incorporating knowledge gains from previous cycles.

In some embodiments, a flow rate sensor is a multiphase flow meter. For example, a multiphase flow meter may include hardware and/or software for determining individual flow rates of different components within a three-phase flow. More specifically, a multiphase flow meter may determine a mass flow rate of a gas component and a mass flow rate of a liquid component (e.g., a component of the three-phase flow that includes oil and water) of the three-phase flow. As such, a multiphase flow meter may be used to determine an amount of oil or a portion of oil within a multiphase flow that travels through a wellhead during a given period of time. A multiphase flow meter may also include hardware that uses various types of sensors based on different sensing technologies (e.g., nuclear magnetic resonance, electromagnetic sensors, acoustic sensors, etc.) and interpretation models. For example, a multiphase flow meter may use a sensor response of magnetic resonance information to determine the number of hydrogen atoms in a particular fluid flow. Since oil, gas, and water each contain hydrogen atoms, properties of a multiphase flow may be measured using magnetic resonance. The hydrogen atoms in a magnetized fluid may respond to radio frequency pulses and emit echoes that are subsequently recorded and analyzed by the multiphase flow meter. Thus, multiphase flow rate measurements may be used for production monitoring, well control, and/or reservoir optimization.

Moreover, a multiphase flow metering system may include a multiphase flow meter and a host device. In response to determining flow rate data regarding a multiphase flow, a multiphase flow meter may transmit flow rate data to a host device, such as a well control system or another type of computer system, over a network. The multiphase flow meter may be coupled to one or more flow tubes in order to determine the flow rate data, such as individual flow rates and/or oil, gas, and/or water fractions of a corresponding multiphase flow. A flow tube may be a fluid conduit, such as pipe, that may provide a fluid sampling for analysis by the multiphase flow meter. Examples of flow tubes may include a bent flow tube, a straight flow tube, or another type of flow tube. Furthermore, a flow model may be stored within a multiphase flow meter as a portion of a database and/or as one or more flow regime maps that are associated with various sensor values. By analyzing sensor data in connection with one or more flow models, a flow meter may determine flow rate data that corresponds to acquired sensor data. Flow rate data may include corresponding fractional data (e.g., gas fraction of a multiphase flow) and/or velocity data (e.g., an individual flow rate of oil or water in the multiphase flow).

Furthermore, the multiphase flow meter may include a flow meter controller that controls sensing operations and/or the flow analysis operations. In some embodiments, a flow controller uses one or more flow models to determine flow rate data regarding a particular flow. Phase distribution information may describe the respective fractions of one or more phases (e.g., gas phase, oil phase, water phase), in a particular flow. Flow regime information may refer to a specific manner that two or three phases flow through a flow tube. For example, a flow regime may be expressed using various superficial velocities. One example of a flow regime may be a “bubble regime,” in which gas is entrained as bubbles within a liquid. Another example of a flow regime is a “slug regime” that may correspond to a series of liquid “slugs” or “plugs” separated by relatively large gas pockets. Accordingly, a flow model may describe changes in a multiphase flow between transitions from high-liquid compositions to high-gas compositions and vice versa. Other flow regimes may include an annular flow regime, a dispersed flow regime, and a froth flow regime.

In some embodiments, one or more production logging tools (PLT) are used to determine production data at one or more depth intervals in a production well. For example, PLT data at a particular depth may include wellbore temperature measurements, pressure measurements, fluid density measurements, flow velocity measurements, and holdup data (e.g., volume fraction of a pipe occupied by fluid). While measurements of pressure, temperature and flow rate can be obtained at the surface, surface measurements may not necessarily reflect what is happening in the reservoir. As such, PLT data may be acquired downhole using various logging tools. More specifically, fluid velocity data may be acquired using a spinner flowmeter. In particular, a spinner flowmeter may include a rotating blade that turns when fluid moves past the device (e.g., the rotational speed of the blade in revolutions per second (RPS) may be proportional to the fluid velocity). Moreover, PLT data may be acquired using a production logging toolstring. This toolstring may include a fullbore spinner, various fluid holdup and bubble count probes, a pipe diameter caliper tool, a bearing sensor, a pressure sensor, a temperature sensor, a gamma ray tool, a casing collar locator, one or more batteries, and/or a data recorder. Other production logging tools include markers/tracers such as oxygen activation logs or radioactive iodine tracer logs as well as anemometers. An anemometer may be an instrument that measures the speed or velocity of gases in a contained flow. As such, PLT operations may include temperature logging, radioactive tracer logging, noise logging, focused gamma ray density logging, unfocused gamma ray density logging, fluid capacitance logging, fluid identification logging in high angle wells, and flowmeter logging at different depth intervals.

Keeping with production logging tools, various types of logging tools may be used to provide information during production operations and afterwards. For example, production logging may determine an axial flow rate based on axial velocity data and an internal diameter of a pipe component. Likewise, production logging may be used to track movement of fluid either inside or immediately outside the casing of a wellbore. Examples of production logs include temperature surveys, mechanical flowmeter surveys, and borehole fluid-density surveys, and fluid-capacitance surveys. Moreover, PLT data may be used to determine whether a production problem exists, such as excessive water or gas production. In particular, PLT data may be used to determine whether a production problem is the result of a completion problem or a reservoir problem. In some embodiments, production logging is used to determine the location of casing damage or collars. Likewise, PLT data may also determine water holdup in a wellbore or a well's gas volume fraction. Thus, PLT data may provide detailed, multiphase evaluation of fluid velocity and phase identification in vertical, deviated, and horizontal wells. More specifically, PLT data may identify fluid entry, gas leaks, injection zones, and cement tops through various well or reservoir analyses.

In some embodiments, a production well system includes a water cut sensor. For example, a water cut sensor may be hardware and/or software with functionality for determining the water content in oil, also referred to as “water cut.” Measurements from a water cut sensor may be referred to as water cut data and may describe the ratio of water produced from the wellbore compared to the total volume of liquids produced from the wellbore. Water cut sensors may implement various water cut measuring techniques, such as those based on capacitance measurements, Coriolis effect, infrared (IR) spectroscopy, gamma ray spectroscopy, and microwave technology. Water cut data may be obtained during production operations to determine various fluid rates found in production from the well system.

With regard to microwave-based water cut sensors, certain microwave-based water cut sensors may rely on measuring a phase difference between transmitted and received microwave signals. As such, the phase difference may have a direct link with the effective permittivity of the oil and water mixture from the wellbore. In some embodiments, microwave-based water cut sensors employ transmit (Tx) antennas and receive (Rx) antennas disposed inside of well system pipe, such that the antennas are at least partially immersed in the fluid mixture as the fluid flows through the pipe.

In some embodiments, a well system includes a water cut sensing system that includes a water cut (WC) sensor, a cylindrical pipe, and/or a measurement processing system. The WC sensor may be disposed on (or otherwise integrated within) the cylindrical pipe. As such, the WC sensor may include a signal conductor (SC) (e.g., a first conductive plane), such as a T-resonator, disposed at a first/upper/top surface of the cylindrical pipe, and a ground conductor (GC) (e.g., a second conductive plane) disposed at a second/lower/bottom surface of the cylindrical pipe that is opposite the first/upper/top surface of the pipe. In such a configuration, the WC sensing system may be employed to sense a water cut of fluid obtained from the wellbore (e.g., a water and oil mixture, or other substrate). In some embodiments, a WC sensor includes multiple waveguides that are attached to a production pipe, where a network analyzer may be connected to the waveguides. The network analyzer may be communicatively coupled with the well control system to determine water cut data.

In some embodiments, a well system includes a logging system. A logging system may include one or more logging tools for use in generating well logs of the formation. For example, a logging tool may be lowered into a wellbore to acquire measurements as the tool traverses a depth interval (e.g., a targeted reservoir section) of the wellbore. The plot of the logging measurements versus depth may be referred to as a “log” or “well log”. Well logs may provide depth measurements of the well that describe such reservoir characteristics as formation porosity, formation permeability, resistivity, water saturation, and the like. The resulting logging measurements may be stored and/or processed, for example, by the control system, to generate corresponding well logs for a well. A well log may include, for example, a plot of a logging response time versus true vertical depth (TVD) across the depth interval of the wellbore.

Turning to examples of logging techniques, multiple types of logging techniques are available for determining various reservoir characteristics (e.g., wireline logging, logging-while-drilling (LWD), and measurement-while-drilling (MWD)). In some embodiments, gamma ray logging is used to measure naturally occurring gamma radiation to characterize rock or sediment regions within a wellbore. In particular, different types of rock may emit different amounts and different spectra of natural gamma radiation. For example, gamma ray logs may distinguish between shales and sandstones/carbonate rocks because radioactive potassium may be common to shales. Likewise, the cation exchange capacity of clay within shales may also result in higher absorption of uranium and thorium further increasing the amount of gamma radiation produced by shales.

Turning to nuclear magnetic resonance (NMR) logging, an NMR logging tool may measure the induced magnetic moment of hydrogen nuclei (i.e., protons) contained within the fluid-filled pore space of porous media (e.g., reservoir rocks). Thus, NMR logs may measure the magnetic response of fluids present in the pore spaces of the reservoir rocks. In so doing, NMR logs may measure both porosity and permeability, as well as the types of fluids present in the pore spaces. Thus, NMR logging may be a subcategory of electromagnetic logging that responds to the presence of hydrogen protons rather than a rock matrix. Because hydrogen protons may occur primarily in pore fluids, NMR logging may directly or indirectly measure the volume, composition, viscosity, and distribution of pore fluids.

Turning to coring, reservoir characteristics may be determined using core sample data acquired from a well site. For example, certain reservoir characteristics can be determined via coring (e.g., physical extraction of rock specimens) to produce core specimens and/or logging operations (e.g., wireline logging, logging-while-drilling (LWD) and measurement-while-drilling (MWD)). Coring operations may include physically extracting a rock specimen from a region of interest within the wellbore for detailed laboratory analysis. For example, when drilling an oil or gas well, a coring bit may cut core plugs (or “cores” or “core specimens”) from the formation and bring the core plugs to the surface, and these core specimens may be analyzed at the surface (e.g., in a lab) to determine various characteristics of the formation at the location where the specimen was obtained.

Turning to various coring technique examples, conventional coring may include collecting a cylindrical specimen of rock from the wellbore using a core bit, a core barrel, and a core catcher. The core bit may have a hole in its center that allows the core bit to drill around a central cylinder of rock. Subsequently, the resulting core specimen may be acquired by the core bit and disposed inside the core barrel. More specifically, the core barrel may include a special storage chamber within a coring tool for holding the core specimen. Furthermore, the core catcher may provide a grip to the bottom of a core and, as tension is applied to the drill string, the rock under the core breaks away from the undrilled formation below a coring tool. Thus, the core catcher may retain the core specimen to avoid the core specimen falling through the bottom of the drill string. In some embodiments, a micro computed tomography (micro-CT) scan is performed on a core sample. Several types of micro-CT scanning may be used, such as a desktop micro-CT scanner that uses an X-ray generation tube, and a synchrotron X-ray micro-tomography. In particular, a micro-CT scanner may use various X-rays to penetrate from different viewpoints in a core sample to produce an attenuated projection profile that is used for later reconstruction using a filtered back projection algorithm.

Furthermore, cutting samples may be acquired and analyzed from one or more drilling operations to determine various geological properties of one or more formations. In particular, cuttings may be initially cleaned in liquid detergent to remove drilling additives and before being dried on a ‘hotplate’. Dried cutting samples may be passed through one or more sieves to remove fragments of various sizes. Likewise, a magnet may be placed over a sieved cutting sample to remove any metallic fragments acquired during a drilling operation. After selecting various desired samples from the sieving and other preparation processes, selected samples may be ground into a fine powder for analysis using X-ray fluorescence (XRF) spectrometry processing and/or and inductively coupled plasma (ICP) spectrometry processing.

Turning to downhole sampling, some embodiments acquire various downhole fluid samples of fluids using one or more downhole sampling devices. Downhole fluid sampling may also be referred to as bottomhole sampling. In particular, downhole fluid samples may include samples of reservoir fluids as well as active production streams above ambient pressure. A downhole sampling operation of a production stream may involve running a sampling tool (e.g., a downhole sampling device) into a well using wireline technology to acquire a fluid sample under the increased pressure of the fluid column. As such, careful well conditioning may be necessary to ensure that the downhole fluid sample is in a monophasic condition. For example, a downhole sampling device may include a timer with a mechanical clock or be connected to the surface by an electric line that conveys an electric triggering signal for acquiring a sample at a predetermined depth or location. In some embodiments, a downhole sampling device may be lowered into the well until the tool is a short distance above the upper limit of a perforated interval to collect a fluid sample that is representative of various production intervals. As an alternative to wireline technology, downhole sampling devices may also be implemented using drillstem and tubing-conveyed installations. In some embodiments, a formation-test tool is a single-phase reservoir sampler (SRS) device that maintains a formation sample in a single-phase condition above reservoir pressure as the SRS device is retrieved from a wellbore. An SRS device may have its own clock for determining when and at what depth to acquire a downhole sample. In some embodiments, a downhole sampling device includes a hydraulic fluid chamber, a sample chamber, a floating piston, a mechanical timer, a triggering system, a hanging head, and a closing mechanism.

In some embodiments, reservoir-fluid samples are acquired using one or more formation-testing tools. For example, a formation-testing tool may be inserted into an openhole well containing drilling mud or completion fluid. Once the formation-testing tool has been run to a predetermined depth, the formation-testing tool may force a probe against the formation. The probe may provide a seal against the borehole wall such that only formation fluid can flow into the formation-testing tool. Likewise, a formation-testing tool may be equipped with various devices designed to collect samples of reservoir fluid in a series of sample chambers. As such, a formation-testing tool may collect reservoir fluid without performing a drill stem test (DST) and flowing fluid to the surface as well as acquiring sample fluids from a number of discrete depths (e.g., for identifying a reservoir fluid gradient).

Keeping with reservoir and downhole sampling, some embodiments use surface-separator sampling where reservoir-fluid samples are recombined in a laboratory. However, recombination procedures may result in gas-oil ratio (GOR) errors and measurement imprecision. As such, downhole sampling may avoid such inaccuracies by acquiring reservoir fluid in a monophasic condition when sampled. Thus, some embodiments use laboratory analyses that include both surface samples at the wellhead and downhole fluid samples to obtain a representative reservoir fluid. For an SRS device, an unaltered sample may be retrieved at the surface in a single-phase state, thus requiring no recombination.

In some embodiments, downhole samples are used to determine wellstream fluid data, such as pressure-volume-temperature (PVT) properties, of one or more regions in an unconventional reservoir. In particular, a PVT laboratory test on a downhole fluid sample may use multiple stages. For example, separator test experiments may be carried out for both oil and gas condensate mixtures. A sample of reservoir fluid may be placed in a laboratory cell and brought to reservoir temperature and bubble-point pressure. Afterwards, fluid may be expelled from the laboratory cell through a number of stages of separation. Usually, two or three stages of separation are used, with the last stage at atmospheric pressure and near-ambient temperature.

Keeping with PVT data, PVT properties may be used for hydrocarbon reserve estimations, reservoir modeling, production and pressure analysis, and for predicting well production performance. Thus, PVT properties may be identified by relating specific properties of unconventional reservoir fluids with various reservoir measurements, such as saturation pressure and oil formation volume factor may be correlated with reservoir temperature, stock tank oil gravity, specific gas gravity, and/or solution gas-oil-ratios. More specifically, PVT may be determined using various PVT correlation methods, such as non-parametric correlation methods that provide a multivariate optimization without using a specific model. Examples of PVT correlation methods may include exponential-polynomial functions and rational polynomial functions. In addition to PVT correlation methods, PVT properties may be further determined using equation-of-state (EOS). Equations-of-state may be computationally complex, thereby requiring detailed compositions of reservoir fluids. An example of EOS is a mathematical function that relates pressure, molar volume, temperature, and composition for modelling a fluid system (e.g., a reservoir region).

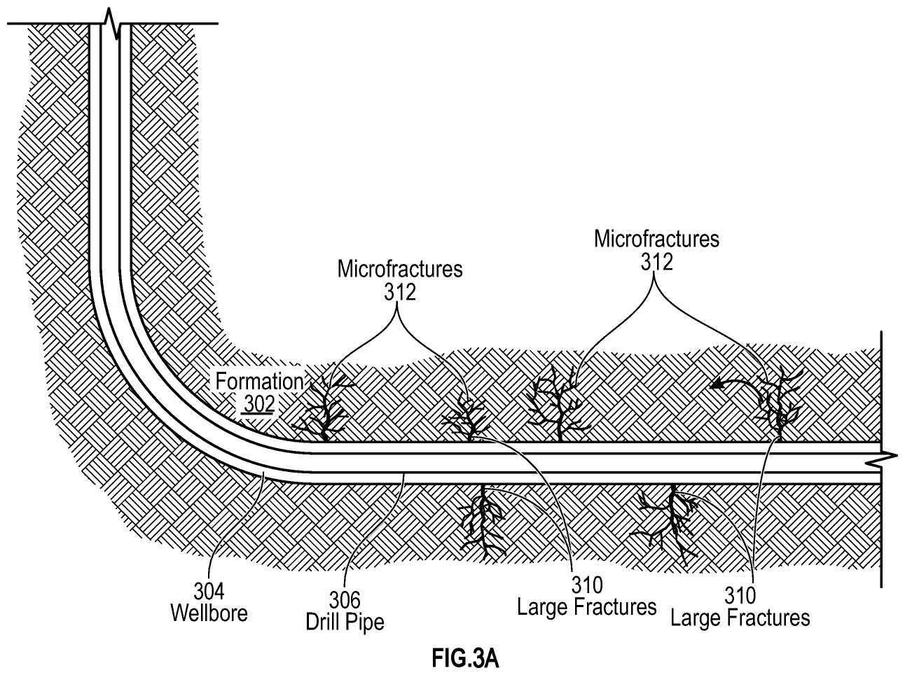

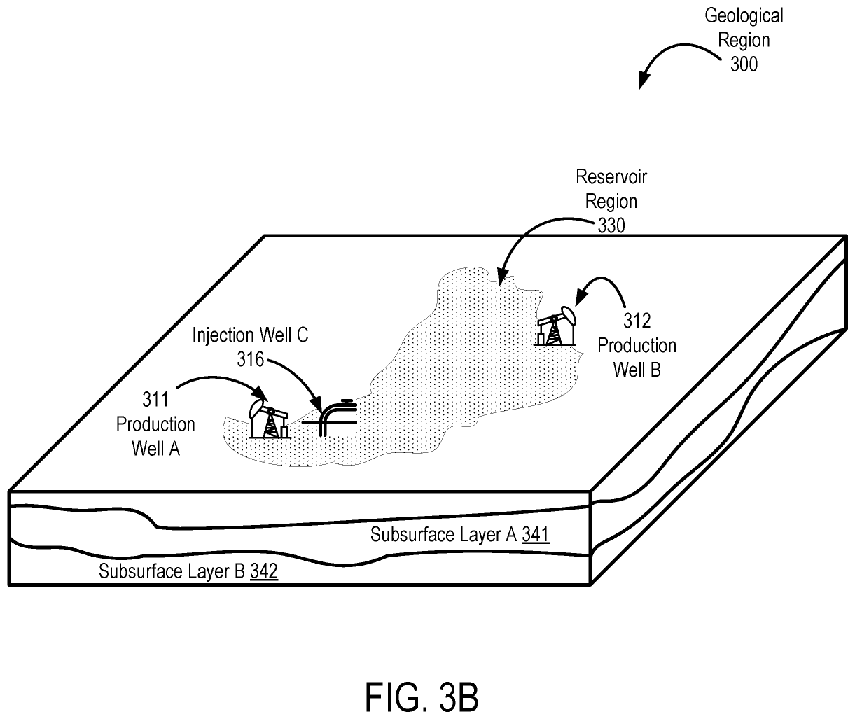

Turning to FIG. 3A, FIG. 3A shows a schematic diagram in accordance with one or more embodiments. As shown in FIG. 3A, FIG. 3A illustrates a hydraulic stimulation operation that forms additional microfractures (312) within a formation (302). More specifically, a wellbore (304) may be located within formation (302), where a casing string (306) is positioned within the wellbore (304). Following a hydraulic fracturing process, for example, large fractures (310) may exist within the formation (302) and extend outward from the wellbore (304). In particular, hydrocarbon reserves may be trapped within certain low permeability formations, such as sand, carbonate, and/or shale formations. Thus, stimulation treatments may be performed by a stimulation control system coupled to a well completion assembly or well completion system that enhances well productivity at one or more wells, where one type of stimulation treatment is hydraulic fracturing. In some embodiments, for example, hydraulic fracturing includes injecting high viscosity fluids into a wellbore at a sufficiently high injection rate so that enough pressure is produced within the wellbore to split the formation. As such, a stimulation operation may be determined that achieves a desired height and/or length of one or more induced fractures.

Keeping with FIG. 3A, various stimulation procedures may be employed that use one or more techniques to ensure that an induced fracture becomes conductive after injection ceases. For example, during acid fracturing of carbonate formations, acid-based fluids may be injected into the formation to create an etched fracture and conductive channels. These conductive channels may be left open upon closure of the induced fracture. With sand or shale formations, a proppant may be included with the hydraulic fracturing fluid such that the induced fracture remains open during or following a stimulation treatment. Likewise, in carbonate formations, a stimulation treatment may include both acid fracturing fluids and proppants. Accordingly, heat produced within a formation, acid, or aqueous water transmitted into the formation may all play a role in producing reactions causing one or more microfractures in a formation.

Keeping with hydraulic fracturing, a hydraulic fracturing operation may include well completion assembly with one or more inflatable packers as well as a work string or casing string (306) that extends within a wellbore. A casing string may include steel casing or pipe that may be divided into surface casing, intermediate casing, and/or production casing. Packers may include inflatable packers that seal an annulus defined between well completion equipment and an inner wall of the wellbore in order to divide a formation into multiple wellbore intervals. These wellbore intervals may be separately or simultaneously stimulated during a hydraulic stimulation operation using a stimulation control system. Thus, in a hydraulic fracturing operation, a hydraulic fracturing fluid may be pumped through the casing string (306) and into a targeted formation using various perforations (i.e., open holes) in the casing string (306).

By injecting the hydraulic fracturing fluid at pressures high enough to cause the rock within the targeted formation to fracture, the hydraulic fracturing operation may “break down” the formation. As high-pressure fluid injection continues, a fracture may continue to propagate into a fracture network. This high pressure for injecting the hydraulic fracturing fluid may be referred to as the “propagation pressure” or “extension pressure.” As an induced fracture continues to grow, a proppant, such as sand, may be added to the fracturing fluid. Once a desired fracture network is formed, the fluid flow may be reversed and the liquid portion of the fracturing fluid is removed. The proppant is intentionally left behind to prevent the fractures from closing onto themselves due to the weight and stresses within the formation. Accordingly, the proppant may “prop” or support the induced fractures to remain open, by remaining sufficiently permeable for hydrocarbon fluids to flow through the induced fracture. Thus, a proppant may form a packed bed of particles with interstitial void space connectivity within a formation. Accordingly, a higher permeability fracture may result from the hydraulic fracturing operation.

In some embodiments, for example, a hydraulic fracturing fluid with an activator is injected into the formation (302), where the fluid migrates within the large fractures (310). Upon a reaction caused by the activator, the injection fluid may produce one or more gases and heat, thereby causing the microfractures (312) to be created within the formation (302). Thus, a stimulation treatment may provide pathways for the hydrocarbon deposits trapped within the formation (302) to migrate and be recovered by a production well. In other words, hydraulic stimulation operations may be applied to formations that easily fracture to produce more microfractures with little plastic deformation under compression.

Furthermore, fracture monitoring may be important to understanding and optimizing hydraulic fracturing treatments. For example, a hydraulic stimulation manager may perform diagnostics that determine various stimulation effects such as fracture geometry, proppant placement in one or more fractures, and/or fracture conductivity. This fracture monitoring may be performed using a distributed acoustic sensing (DAS) system implemented within a wellbore. In some embodiments, a DAS system includes various fiber-optic sensors (e.g., distributed over a single mode optical fiber several kilometers in length). As such, backscattered light may be measured and further analyzed using signal processing techniques to enable a DAS system to segregate an optical fiber into an array of individual acoustic receivers. More specifically, various pulses of light may be transmitted along the optical fiber, where characteristics of the backscattered light may change due to acoustic vibrations disturbing the casing of the optical fiber. Through DAS processing, the location of these disturbances may be identified.

Keeping with DAS systems, pumping operations may produce various acoustic signals along a wellbore and the adjacent fractures, where the acoustic sensing data depends upon geometrical and physical attributes of the propagating fractures. Accordingly, a quantitative DAS inversion may determine various fracture properties in hydraulic fracture monitoring. For example, a wellbore may be profiled in real time by removing DAS pump noise data and matching acquired data to a forward model regarding pulse propagation in the wellbore and adjacent fractures. Thus, DAS inversion may identify various hydraulic stimulation features such as tubing expansion, fluid-to-fluid interfaces, an adjacent hydraulic fracture, presence of a porous reservoir, and/or an annular compartment. During initial phases of a hydraulic stimulation operation, DAS inversion may determine location information of wireline logging equipment within a wellbore. For example, DAS techniques may verify whether perforating guns and packer-setting devices are disposed at desired depths in the wellbore. In some embodiments, DAS inversion is performed using additional data from distributed temperature sensors (DTS) and/or micro-seismic monitoring techniques.

In certain unconventional formations, for example, an important element that determines whether it is economically viable to develop a reservoir is the presence of one or more sweet spots in the reservoir. A sweet spot may be generally defined herein as the area within a reservoir that represents the best production or potential for production. In a particular geological region, the sweet spot may be determined based on a lack of ductility, a destruction of internal cohesion, an ability for a rock to deform and fail with a low degree of inelastic behavior, and a rock's capability for self-sustaining fracturing. Likewise, sweet spots may include intervals within organic shales, which possess the highest relative hydrocarbon yield for drilling purposes.

Keeping with sweet spots, sweet spot identification may be used by a reservoir simulator to identify one or more drilling location for unconventional wells. In particular, a sweet spot may be determined with certain reservoir characteristics such as reservoir quality and completion quality based on predicted hydrocarbon data, reservoir data, well log data, seismic data, etc. As such, various technologies may be used to extract resources from unconventional reservoirs at certain sweet spots, such as hydraulic fracturing and horizontal wells.

With respect to proppant systems, a well completion system may include a proppant system. A proppant system may include transfer devices, such as chutes and conveyor belts, for transferring a propping agent (also called simply “proppant”) to a fluid mixing system. Likewise, a proppant system may include one or more proppant storage devices, such as a silo, and a housing. In particular, a silo may use fill ports for acquiring propping agents, which may be subsequently transferred to a fluid mixing system using drain valves and/or outlet ports. The proppant system may then dispense the propping agent to the fluid mixing system for producing a stimulation fluid.

Moreover, a stimulation treatment for a formation may be updated by a reservoir simulator using a geological model. For example, a reservoir simulator may use a geological model to perform one or more stimulation simulations using different injection fluid pressure rates, different types of proppants, acid-based treatments and non-acid treatments, etc., to determine a desired stimulation scenario for the formation.

Turning to FIG. 3B, FIG. 3B shows a schematic diagram in accordance with one or more embodiments. As illustrated in FIG. 3B, FIG. 3B shows a geological region (300) that may include one or more reservoir regions (e.g., reservoir region (330)) with various production wells (e.g., production well A (311), production well (312)). Likewise, a reservoir region may also include one or more injection wells (e.g., injection well C (316)) that include functionality for enhancing production by one or more neighboring production wells. As shown in FIG. 3B, wells may be disposed in the reservoir region (330) above various subsurface layers (e.g., subsurface layer A (341), subsurface layer B (342)), which may include hydrocarbon deposits. In particular, production data and/or injection data may exist for a particular well, where production data may include data that describes production or production operations at a well, such as wellhead data.

While FIGS. 1, 2, 3A, and 3B shows various configurations of components, other configurations may be used without departing from the scope of the disclosure. For example, various components in FIGS. 1, 2, 3A, and 3B may be combined to create a single component. As another example, the functionality performed by a single component may be performed by two or more components.

Turning to FIGS. 4A and 4B, FIG. 4A and 4B show flowcharts in accordance with one or more embodiments. Specifically, FIG. 4A describes a general method for determining and/or validating a reservoir development plan in accordance with one or more embodiments. Likewise, FIG. 4B describe another workflow in accordance with one or more embodiments. One or more blocks in FIG. 4A may be performed by one or more components (e.g., reservoir development manager X (260)) as described in FIGS. 1, 2, 3A, and 3B. While the various blocks in FIG. 4A are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 400, a screening criterion and/or a ranking criterion is obtained for generating a reservoir development plan in accordance with one or more embodiments. For example, a reservoir development manager may obtain one or more screening criteria or one or more ranking criteria from user inputs to a user device or a database that is associated with a particular reservoir development plan. Screening criteria may include various predetermined thresholds (e.g., thresholds selected by a user or automatically determined by the reservoir development manager) for filtering or removing various wells and well operations from a reservoir development plan. For example, a screening criterion may correspond to a predetermined threshold for a probability of commerciality. For example, if a predicted amount of hydrocarbon production at a predicted price level does not exceed a cost range for developing a specific production well, the screening criterion may identify the production well as lacking a probability of commerciality. As such, the production well may not be selected for development in the geological region of interest.

In contrast to a screening criterion, a ranking criterion may determine a priority order that production wells are developed and/or well operations are performed in one or more geological regions. Rather than removing a particular well or well operation from a reservoir development plan, a ranking criterion may be used to determine a production well ranking that identifies an order that different wells are developed in a geological region. For example, wells with a higher certainty of achieving a predetermined level of commerciality may be selected for development prior to other wells with a greater range of uncertainty for hydrocarbon production or increased cost risks for development.

In Block 405, well data are obtained for one or more wells in accordance with one or more embodiments. For example, the well data may be similar to the well data described above in FIGS. 1 and 2 and the accompanying description.

In Block 410, resource development data are obtained for a geological region of interest in accordance with one or more embodiments. For example, resource development data may describe different criteria for measuring success at a particular stage of a reservoir development plan. Examples of resource development data may include expected production quantities of hydrocarbons, cost thresholds for developing a reservoir region or one or more wells, as well as scheduling data for performing one or more stages within a predetermined amount of time or by a particular date.

In some embodiments, scheduling data is historical scheduling data that is used to determined amounts of schedule variation in performing one or more well operations. In particular, delay in one well operation may result in delays in later well operations. If a drilling operation falls behind on a drilling schedule, the delay may result in various completion operations that are required to achieve a production well. As such, scheduling data may be used in a stochastic assessment to determine amounts of uncertainty (i.e., schedule variation) in achieving a schedule associated with a reservoir development plan.

In Block 415, drilling cost data, production cost data, and/or well completion cost data are obtained for one or more wells in accordance with one or more embodiments. For example, cost data may be obtained from various service providers over a computer network. Likewise, cost data may be collected from historical well operations for similar wells or similar types of reservoirs.

In Block 420, geological failure data and/or mechanical failure data are obtained regarding one or more wells in accordance with one or more embodiments. Geological failure data may include risk data associated with developing a reservoir region in one or more formations, such as costs overruns based on drilling or completing a well with various geological properties. Likewise, geological failure data may include risk data regarding whether production at one or more wells in the reservoir region satisfy predetermined quantities. Mechanical failure data may include risk data associated with drilling operations, well completion operations, and/or well maintenance operations.

In Block 430, a stochastic assessment of a geological region of interest is determined based on a screening criterion, a ranking criterion, one or more stochastic models, well data, reservoir development data, drilling cost data, well completion cost data, well production cost data, geological failure data, and mechanical failure data in accordance with one or more embodiments. In particular, a stochastic assessment may provide a forecast of probabilities of various well scenarios under different conditions using random variables. For example, a stochastic assessment may presents predicted well operation data in a graphical user interface and predicts various well outcomes that account for certain levels of unpredictability or randomness. As such, a stochastic assessment may include well production curves, cost curves, and schedule variation curves, along with predicted amounts of uncertainty for the predicted data. In some embodiments, a stochastic assessment determines a probability of commerciality based on the current input data as well as the level of uncertainty for this probability of commerciality.

In some embodiments, one or more stochastic assessments are determines using one or more Monte Carlo simulations. Monte Carlo simulations may be used Monte Carlo methods are useful for simulating reservoir systems with many coupled degrees of freedom, such as a reservoir region with different reservoir fluids, different types of formations, different types of well operations (e.g., vertical wells and horizontal wells with corresponding hydraulic stimulation operations), and different related costs based on available service provides and geographic locations. In some embodiments, a Monte Carlo simulation produces one or more probability distributions for describing costs of developing a particular well, schedule variation in achieving a final production well, and costs associated with one or more well operations (e.g., exploratory operations, drilling operations, and well completion operations).

In Block 440, a reservoir development plan is generated using a stochastic assessment of a geological region of interest in accordance with one or more embodiments. Using different types of data, a reservoir development plan may be generated by a reservoir development manager that accounts for various outcomes of different projects (e.g., exploratory projects, pilot stages, production operations, etc.). Likewise, different reservoir development plans may be adjusted iteratively as new data is collected over a well management network. For example, a reservoir development plan may be adjusted through performance of the reservoir development plan, such as to account for changing economic conditions, changes to oil field technology, and/or access to more well data regarding the geological region of interest. Based on new data, an adjusted reservoir development plan may be determined accordingly.

In Block 445, a reservoir development plan is presented within a graphical user interface in accordance with one or more embodiments. For example, multiple reservoir development plans may be displayed on a user device with different types of risks and/or probabilities of success. In particular, a graphical user interface may illustrate a range of drilling costs, a range of completion costs, and a range of maintenance costs for a predicted production well. In some embodiments, the graphical user interface illustrates an amount of schedule variation in implementing one or more well operations for one or more production wells. Likewise, a particular production well in a reservoir development plan may be associated with a predicted range of hydrocarbon production using available data.

In Block 450, a determination is made whether to change a reservoir development plan based on new data in accordance with one or more embodiments. For example, the new data may correspond to new well data, new cost data, new geological failure data, and new mechanical failure data from a different time interval than the data collected in Blocks 405, 415, and 420. In some embodiments, new data is collected over a well management network in real time, such as from various control systems managing various well operations. Where it is determined that the reservoir development plan does not need to be updated, this process may proceed to Block 470. Where it is determined that the reservoir development plan needs to be updated, this process may proceed to Block 460.

In Block 460, an adjusted stochastic assessment is determined using new data and/or a different screening criterion in accordance with one or more embodiments.

In Block 470, one or more commands are transmitted to adjust and/or implement various well operations based on a reservoir development plan in accordance with one or more embodiments. For example, a reservoir development manager may communicate with one or more control systems at multiple well sites in order to implement various sub-tasks in a reservoir development plan according to a desired timeline. In some embodiments, the reservoir development plan includes various hydraulic stimulation operations for developing one or more unconventional reservoirs. As such, the reservoir development manager may coordinate various stimulation operations with one or more stimulation control systems, such as based on a production well ranking or other scheduling data associated with a reservoir development plan.

In some embodiments, a reservoir development manager performs the process described in FIGS. 4A and 4B above using data inputs based on contracts, service providers, materials, a scope of work for a well operation, a cost of the well operation, and various restrictions (such as alternate restrictions for different well scenarios). For example, the reservoir development manager may independently access each data input in the context of a screening criterion (e.g., assign the data input no weight or significant weight in analyzing a stochastic assessment). The reservoir development manager may arrange the stages of a possible reservoir development plan to restrict and/or arrange multiple options among projects for implementing the reservoir development plan. Once a reservoir development plan is determined, a reservoir development plan may provide a schedule of various tasks for implementing the reservoir development plan. The reservoir development plan may be displayed with various conflicts and awareness being highlighted. The reservoir development manager may decide if an adjustment is needed based on newly acquired data or a new analysis of existing data. Likewise, the reservoir development manager may send a request to a user device for feedback regarding the existing reservoir development plan. Once a final reservoir development plan with a final schedule is drafted, the plan may proceed to final approval. At final approval, a reservoir development manager may validate the plan based on whether existing conflict checks are observed. In some embodiments, the well intervention play may be approved and/or revised by users.

In some embodiments, a ML algorithm trains a model to build and/or adjust a reservoir development plan based on specific input features (e.g., data inputs). For example, the reservoir development manager may build multiple reservoir development plans within seconds to accommodate multiple sets of data inputs for different stochastic assessments depending on the user defined importance of different variables. Some variables may be flexible to change when required (swap importance relevance of setup by incidents, cost, contract, performance, etc. among screening criteria and/or ranking criteria). The reservoir development manager makes decisions regarding whether a reservoir development plan, a screening criterion, and/or a ranking criterion need adjustment.

Furthermore, the reservoir development manager assesses the statistical trend of data inputs as an additional value to enhance the automatic machine learning self-decision process of the schedule. Thus, the reservoir development manager may allow flexibility to accommodate real-time changes on the fly for any observed matters (e.g., safety concerns, government, weather, legal, etc.) to improve robustness of reservoir planning by advising about possible issues. The reservoir development manager may assess reservoir development plans for different reservoir scenarios in order to better arrange and/or adjust a forward schedule based on the obtained real-time data from actual processes and real events. As such, the reservoir development manager accommodates substantial amount of site planning, emerging issues, and rescheduling well operations.

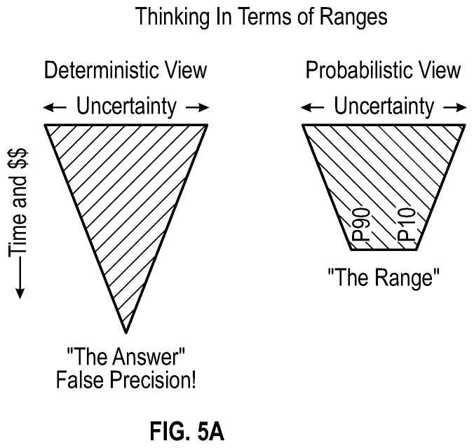

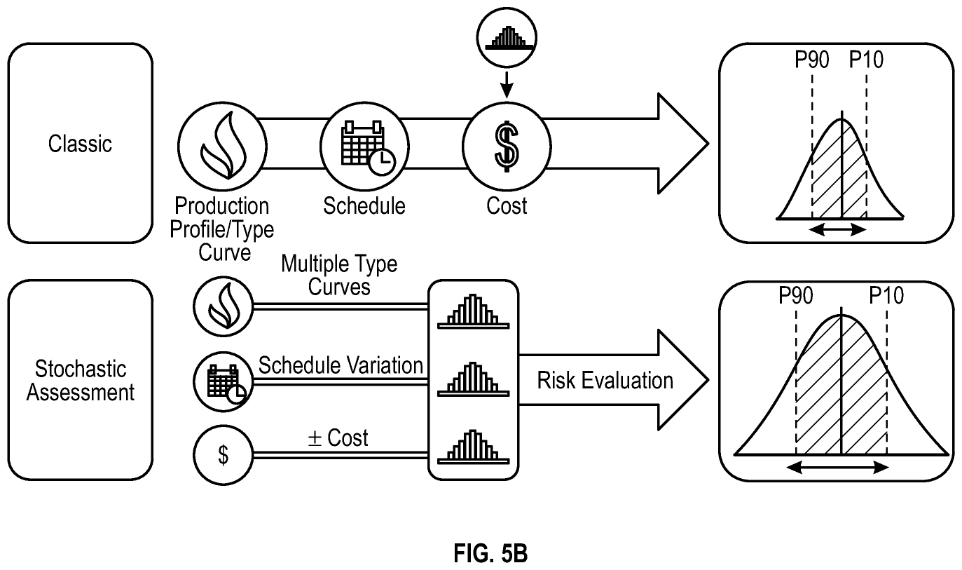

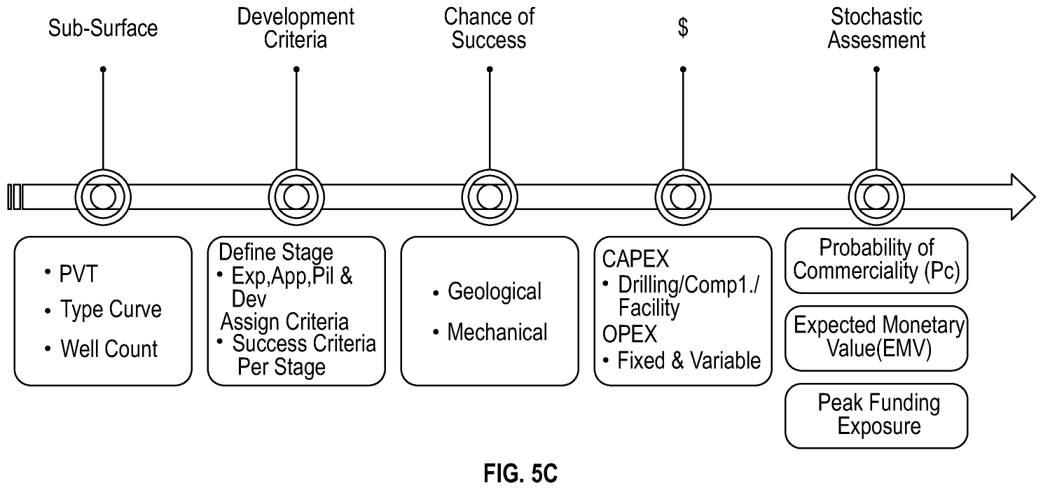

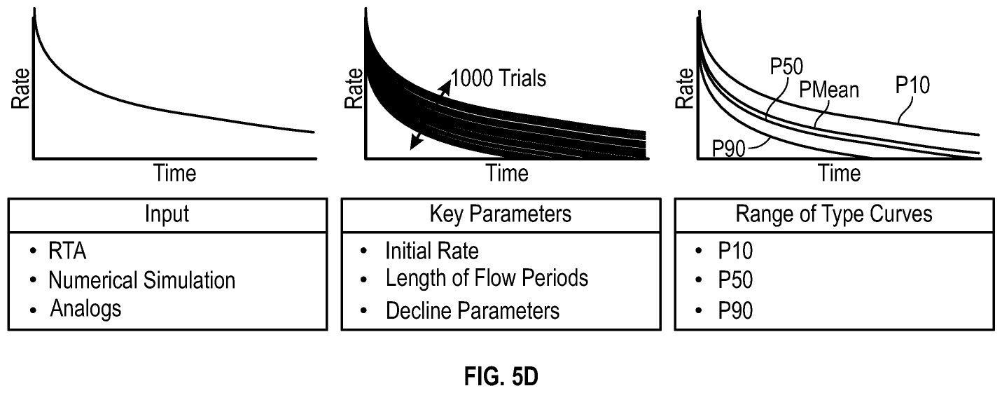

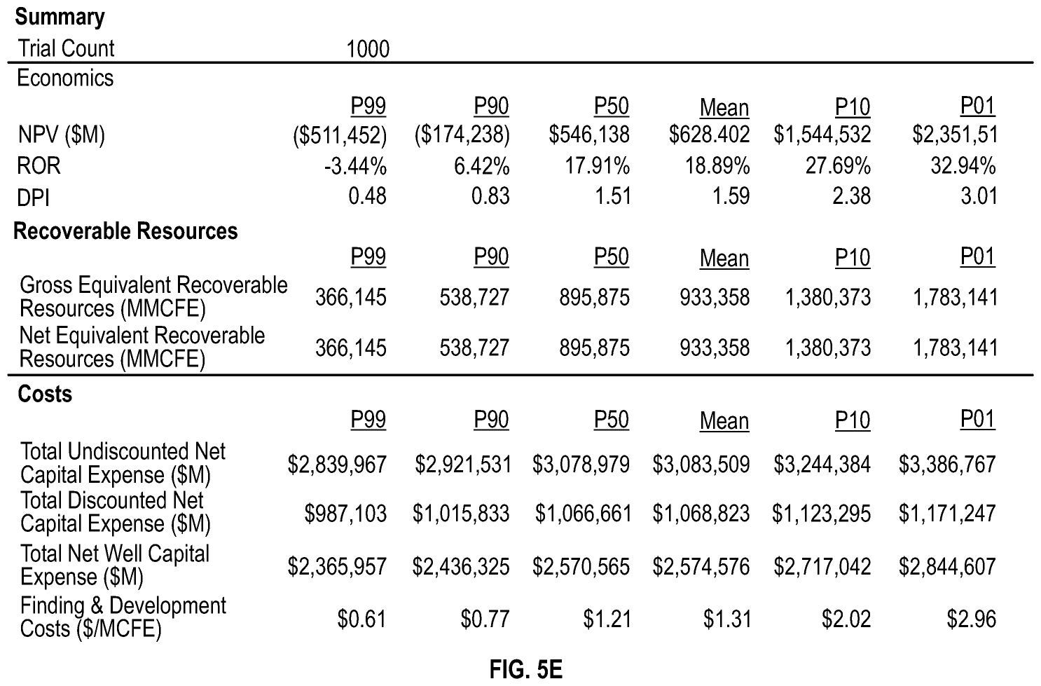

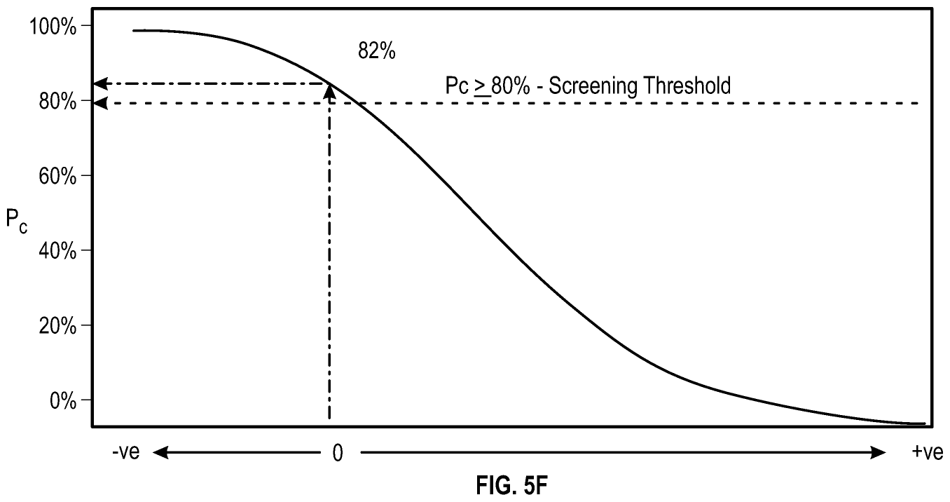

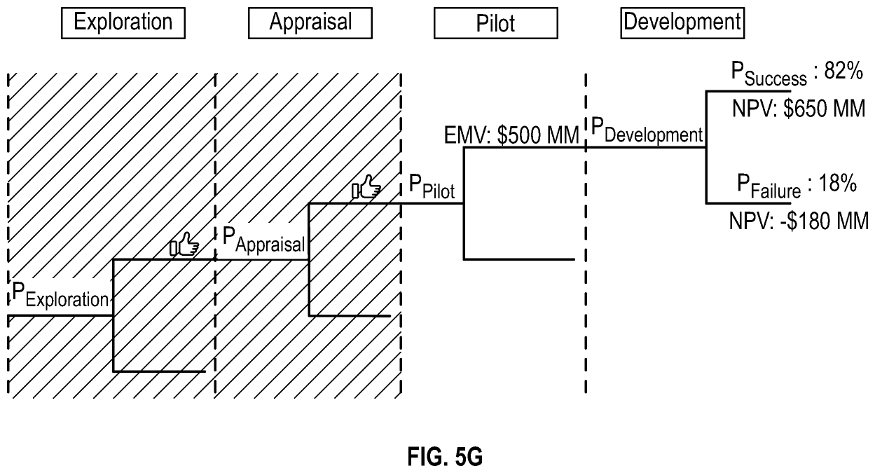

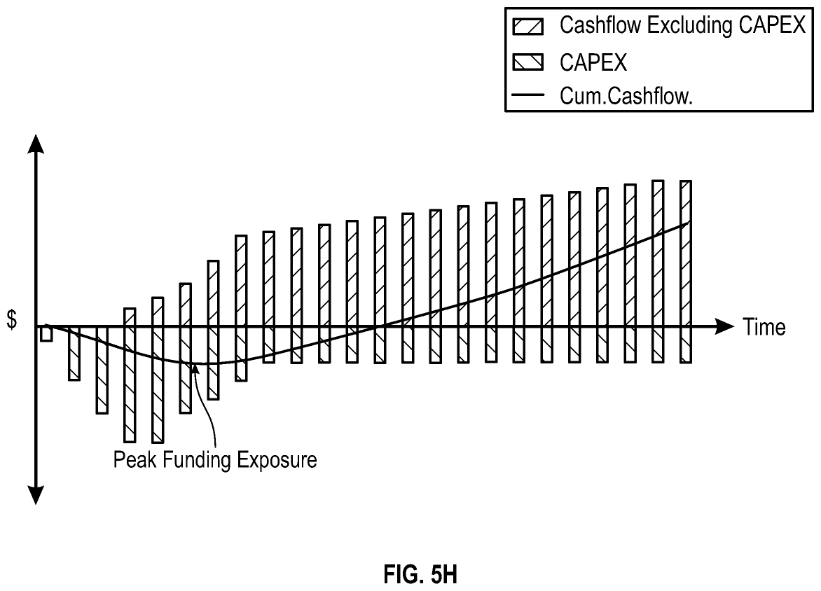

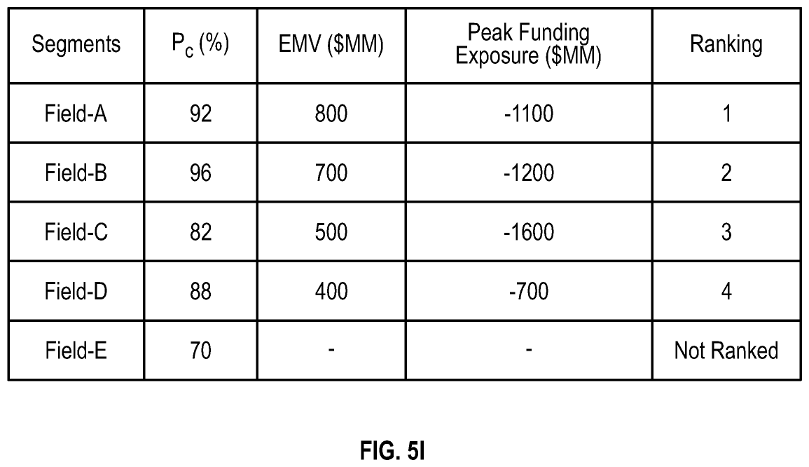

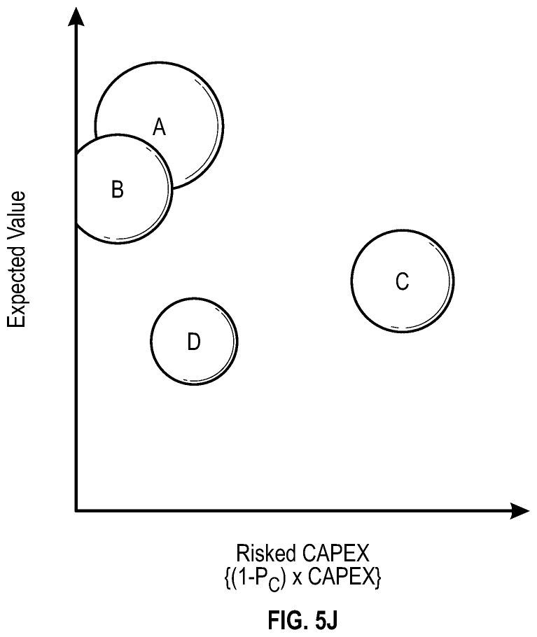

Turning to FIGS. 5A, 5B, 5C, 5D, 5E, 5F, 5G, 5H, and 5I, FIGS. 5A-5I illustrates various examples in accordance with one or more embodiments. In particular, the examples as illustrated in FIGS. 5A-5I may performed using techniques describes above in FIG. 4A or FIG. 4B. Likewise, some traditional stochastic approaches in project economics may be used for screening and ranking different unconventional plays and other plays that may limit user visibility of all possible outcomes in a project. However, some embodiments describe integrated stochastic workflows with data from various sub-surface and commercial entities to provide a scientific investigation of one or more ranges of possible outcomes. The result may be particular ranking criteria to assist decision makers, such as a reservoir development manager, with making informed decisions in support of a portfolio strategy. For example, sequencing and ranking these individual fields may be used to maximize value is at the core of the appraisal and pilot planning stages.

Furthermore, this understanding of different outcomes of various opportunities at early phases with an appreciation for all uncertainties may be pivotal to good decision making for reservoir development purposes. In early stages, limited data may be available from various well sources, cost sources, etc., and some embodiments may simultaneously address volumetric, producibility and cost uncertainties to determine the potential success of a hydrocarbon opportunity.

In a typical unconventional tight gas play setting, concurrent with surface and subsurface teams commencing field development planning, the exploration and appraisal team may continue work to assess incremental opportunities that can be sequenced and stacked to sustain long-term production and enhance value creation. Our aim is to address the uncertainty and risk of these opportunities by implementing a methodical screening and ranking process. The aim is to evaluate these multiple opportunities and provide relative portfolio risk.

Project screening and ranking is inevitable even when an organization faces no resource bottlenecks. Achieving strategic objectives with an eye for value creation is the backbone of any organization. Thus, some embodiments implement an integrated stochastic workflow that addresses the sub-surface, surface and cost uncertainties to screen, rank and high-grade opportunities early in the de-risking process. As such, various decisions may be efficiently selected and analyzed in the appraisal and pilot stage.

Turning to FIG. 5A, FIG. 5A illustrates a difference between model inputs and various output ranges in accordance with one or more embodiments. Some embodiments may use a unique stochastic workflow to simultaneously address all the technical and commercial uncertainties with a Monte-Carlo model and predict a range of possible outcomes with custom built analysis tools. In other words, some embodiments may determine complete unbiased sample randomness in the expected project outcomes. The proposed workflow may also create a stage gate decision tree approach and review possible outcomes as a series of staged investments. For example, some embodiments, may set up decision review points, targets, economic metric thresholds and use multiple realizations to calculate probability weighted outcomes. This may help to responsibly expose incremental capital in the life cycle of a project and help with course correction where necessary.

In some embodiments, a reservoir development manager implements a value addition stochastic approach. A deterministic approach is the traditional method that may be used in a project evaluation inclusive of screening and ranking. Such an approach may apply a single set of inputs and provides a single output. A common practice in the oil and gas industry may be to simply examine low, mid and high cases. This may be a limited view of possible scenarios and provide a false sense of precision regarding expected project outcomes.

Keeping with stochastic approaches, stochastic may refers to a property of being described by a random probability distribution. Applying stochastics to reservoir development modelling may be based on an understanding that the economic phenomena and connections between them are considered to have a stochastic behavior. Some embodiments use methods and techniques based on the movement of economic phenomena and relations specific to probability theory and mathematical statistics. Likewise, stochastic nature of economic phenomena may be related to predicting multiple possible realities. A stochastic approach may have several distinct advantages and some of the key points. For example, a stochastic model may address various uncertainties in inputs with complete unbiased randomness in the outcomes. Thus, various scientifically possible combination of variables may be calculated accordingly. Moreover, by running thousands of calculations, using many different estimates of future economic conditions, stochastic models may predict a range of possible future investment results showing the potential upside and downside of each scenario. Once the workflow is followed and a stochastic model is setup, multiple realizations can be automated by a reservoir development manager or a user input from a user device. In some embodiments, distribution types and ranges for variables are setup such that if known data is limited, wide ranges are used for outcomes from the input data.

In some embodiments, a reservoir development manager implements an integrated stochastic methodology. For example, a mean or deterministic view of a production profile along with one view of a schedule may be taken and blended with probabilistic distributions on various inputs, such as drilling costs and subsurface data. As such, a Monte Carlo model may be used create multiple scenarios to predict a range of possible outcomes. Thus, a reservoir development manager may use a range of outcomes that cover the uncertainty in cost as well as variability in well performance and reservoir development time.

Turning to FIG. 5B, FIG. 5B illustrates a comparison of various stochastic approaches in accordance with some embodiments. For example, some embodiments may apply stochastic ranges simultaneously to production profiles or different types of well curves, schedules, and well costs. Likewise, some embodiments may identify cases with lower well performance, delayed executions, and higher costs amongst other cases, limited only by the identified uncertainty for each input variable among the data sources. In other words, some embodiments may provide unbiased randomness in expected project outcomes. Thus, a much wider range of uncertainty may be captured accordingly. Some embodiments may provide the flexibility and granularity to model all details of different unconventional projects in order to determine a staged approach to reservoir development decisions. Likewise, some embodiments may perform a periodic review of opportunities on a continual basis and provide high-level visibility for identifying attractive projects and thus facilitate enhanced decision regarding hydrocarbon exploration and drilling new wells for production and/or stimulation.

In some embodiments, a reservoir development manager uses a probabilistic model. Some embodiments provide a probabilistic model to effectively model uncertainties and take them through different stage gates using a monte carlo simulation. For example, a reservoir development manager may integrate sub-surface data, surface data, and/or cost data that includes well counts, production type curves, produced fluid yields (e.g., condensate & natural gas liquid (NGL) ratios), project stages (e.g., exploration, appraisal, pilot and development), project cycle times, capital expenditure (CAPEX) and operating expenditures (OPEX), success criteria, and any other variables that may affect reservoir development evaluation with a stochastic workflow. Likewise, some embodiments use various probability distributions to provide an improved method of describing uncertainty of various inputs for risk analysis. For example, a reservoir development manager may set up probabilistic distributions for different inputs, such as sub-surface well data, surface well data, geological failure data, mechanical failure data, and cost data.

Turning to FIG. 5C, FIG. 5C illustrates an integrated unconventional stochastic workflow in accordance with one or more embodiments. As shown in FIG. 5C, some embodiments use different data sources for screening, ranking, capital allocation and decision making. Thus, several approaches may capture variability in well performance within reservoir development. For example, early-stage screening may have the largest uncertainty in a project with respect to expected well performance. The initial rates, decline factors and ultimate expected recovery per well (EUR) may be limited to short term flow back data, analogue information, and numerical simulation. Understanding of well performance may be important to determining the viability of a project. Likewise, some embodiments provide the ability to capture variability in expected well performances. A single type curve may be expressed as a single or a multi segment analytical equation. Likewise, key input parameters such as initial rate, decline factor, and length of flow periods may be used with distribution ranges and Monte Carlo simulations to determine a multitude of expected type curves. Knowledge from rate transient analysis of flowback data may thus be used to capture reservoir and engineering uncertainty. Thus, different type curves may be applied to assess stochastically a project.

Turning to FIG. 5D, FIG. 5D shows a stochastic approach to various type curves in accordance with one or more embodiments. Probabilistic analysis may provide a stress test the robustness of a hydrocarbon opportunity at the early stages of the project. As such, some embodiments may ensure high graded opportunities are advanced to appraisal and piloting to achieve a desired production strategy. An integrated stochastic model for hypothetical opportunities with synthetic assumptions are shown in FIG. 5D. Multiple realizations may be determined with the help of Monte Carlo simulations and different realizations may go through full field project analyses. For example, various metrics may be used as good indicators for comparison between cases for analyzing the range of outcomes and for quick screening, ranking, and prioritization. Examples of metrics may include probability of commerciality (PC), expected monetary value (EMV), and peak funding exposure. FIG. 5E illustrates a table that shows a stochastic assessment of one opportunity. Multiple realizations of a stochastic approach may lead to a decision tree insight into the chance of success for a particular project. Likewise, stochastic assessments may provide an indication of the chance of success of the project at different stages of the project. Thus, some embodiments may define clear targets and metrics for each stage to determine review/decision points for users and automated algorithms to decide whether to move a project forward. The aim may be to reach an expected monetary value of a project versus a risked capital expenditure to compare and evaluate multiple opportunities.

Turning to probability of commerciality, the probability of commerciality (PC) may be used as a screening criterion of projects. The PC may be expressed as a percentage representing the probability of the opportunity having a net present value (NPV) greater $0 and thus deemed ‘commercial’. The probability of commerciality may be determined based on multiple realizations of the stochastic workflow. FIG. 5F illustrates reverse cumulative probability chart, where the NPV is on the horizontal axis and cumulative probability is on the vertical axis. Likewise, FIG. 5F provides a diagnostic plot that provides the probability of success for an opportunity at a given stage. FIG. 5F shows that 82% of time, the NPV is greater than zero, which may indicate a >80% chance that the project will be a success. For a development assessment, a screening criterion may have a threshold that is set to graduate projects. For example, any project with Pc >80% may be considered screened and submitted for ranking with other projects. This threshold may be determined by a user input set based on the user's experience.

Turning to expected monetary value (EMV), expected monetary value may be an integral part of a project evaluation and may be used to perform a quantitative risk analysis process. An EMV metric may be a specific analytical technique in which a calculation is made to determine the average of all potential outcomes when the future includes a number of specific scenarios that may or may not ultimately happen. An EMV value may be obtained by multiplying the net present value of each possible outcome with the probability of occurrence, i.e., the sum of probability weighted outcomes may correspond to the Expected Monetary Value. As such, an EMV value may be an output from the decision tree analysis.

In the example below, a project may move from a pilot stage to a development stage. The results of UR stochastic analysis indicate 82% chance of success of and 18% chance of failure. Based on this, the Expected monetary value is $500 MM. In FIG. 5G, an illustrative decision tree is show that includes multiple project stages, such as an exploration stage, an appraisal stage, a pilot stage, and a development stage.

Turning to peak funding exposure (PFE), peak funding exposure may be a metric that provides a maximum net funding exposure before net annual cash flows turn positive. With peak funding exposure, a user's risk appetite may be determined in pursuing a project after the project ranking. In FIG. 5H, a sample cashflow analysis is shown below, where the green bars represent revenue, the red bars represent expenditures, and the black line is the cumulative cashflow of the project. More specifically, peak funding exposure may refer to the lowest point on the cumulative cashflow curve. The PFE metric may provide a useful barometer to gauge how much money may be lost or how much money may be needed to fund a project.

In some embodiments, screening, ranking, and prioritization of the portfolio may be a structured, auditable, and repeatable approach that can be applied on opportunity inventory and enabled with the above metrics from the integrated stochastic workflow. Opportunities may be screened, ranked, and prioritized for the decision making for the next stage of investment.

Turning to FIG. 5I, FIG. 5I is an example of portfolio screening and ranking that may be completed to a streamline capital allocation for the most value accretive appraisal/pilot strategy. As shown in FIG. 5I, opportunities may have more than 80% probability of commerciality (PC) are taken forward to ranking among other projects. An EMV metric may rank these opportunities from highest to lowest value. The peak funding exposure may provide the flexibility to adjust the ranking based on a user's risk appetite. Thus, a holistic UR stochastic approach may provide an auditable, trackable, and repeatable ranking process that can be reviewed periodically.

Turning to FIG. 5J, FIG. 5J shows a plot that can be sued for translating the insights from an integrated stochastic workflow into actionable intelligence, i.e., risked CAPEX vs. Expected Monetary Value. The horizontal axis in FIG. 5J shows risked capital while the vertical axis shows the EMV, while the size of the bubble indicates the relative size of the EMV. This plot provides users with a quick visual of the risked capital to Expected Monetary Value of the opportunities with the portfolio. This may not be a one-time process, but rather a process to be routinely repeated as one matures the portfolio with additional data from appraisal and piloting activities. As such, some embodiments provide an integrated stochastic workflow that is an auditable and unbiased de-risking process to aid in assessing commerciality and ranking of project opportunities. Some of the benefits of stochastic analysis may include the following: (1) a consistent and repeatable approach to compare projects; (2) responsibly expose incremental capital and allocate funds to competing ventures; (3) guide stage gate decisions, such as whether to continue the project or exit; (4) quantifying the opportunity both volumetrically and economically; (5) determining the uncertainties and risks that control the variance in production and profitability; (6) comparing projects using a set of standard metrics to determine which are most worthy of continued investment.

Embodiments may be implemented on a computer system. FIG. 6 is a block diagram of a computer system (602) used to provide computational functionalities associated with described algorithms, methods, functions, processes, flows, and procedures as described in the instant disclosure, according to an implementation. The illustrated computer (602) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (602) may include a computer that includes an input device, such as a keypad, keyboard, touch screen, or other device that can accept user information, and an output device that conveys information associated with the operation of the computer (602), including digital data, visual, or audio information (or a combination of information), or a GUI.

The computer (602) can serve in a role as a client, network component, a server, a database or other persistency, or any other component (or a combination of roles) of a computer system for performing the subject matter described in the instant disclosure. The illustrated computer (602) is communicably coupled with a network (630). In some implementations, one or more components of the computer (602) may be configured to operate within environments, including cloud-computing-based, local, global, or other environment (or a combination of environments).

At a high level, the computer (602) is an electronic computing device operable to receive, transmit, process, store, or manage data and information associated with the described subject matter. According to some implementations, the computer (602) may also include or be communicably coupled with an application server, e-mail server, web server, caching server, streaming data server, business intelligence (BI) server, or other server (or a combination of servers).

The computer (602) can receive requests over network (630) from a client application (for example, executing on another computer (602)) and responding to the received requests by processing the said requests in an appropriate software application. In addition, requests may also be sent to the computer (602) from internal users (for example, from a command console or by other appropriate access method), external or third-parties, other automated applications, as well as any other appropriate entities, individuals, systems, or computers.

Each of the components of the computer (602) can communicate using a system bus (603). In some implementations, any or all of the components of the computer (602), both hardware or software (or a combination of hardware and software), may interface with each other or the interface (604) (or a combination of both) over the system bus (603) using an application programming interface (API) (612) or a service layer (613) (or a combination of the API (612) and service layer (613). The API (612) may include specifications for routines, data structures, and object classes. The API (612) may be either computer-language independent or dependent and refer to a complete interface, a single function, or even a set of APIs. The service layer (613) provides software services to the computer (602) or other components (whether or not illustrated) that are communicably coupled to the computer (602). The functionality of the computer (602) may be accessible for all service consumers using this service layer. Software services, such as those provided by the service layer (613), provide reusable, defined business functionalities through a defined interface. For example, the interface may be software written in JAVA, C++, or other suitable language providing data in extensible markup language (XML) format or other suitable format. While illustrated as an integrated component of the computer (602), alternative implementations may illustrate the API (612) or the service layer (613) as stand-alone components in relation to other components of the computer (602) or other components (whether or not illustrated) that are communicably coupled to the computer (602). Moreover, any or all parts of the API (612) or the service layer (613) may be implemented as child or sub-modules of another software module, enterprise application, or hardware module without departing from the scope of this disclosure.

The computer (602) includes an interface (604). Although illustrated as a single interface (604) in FIG. 6, two or more interfaces (604) may be used according to particular needs, desires, or particular implementations of the computer (602). The interface (604) is used by the computer (602) for communicating with other systems in a distributed environment that are connected to the network (630). Generally, the interface (604 includes logic encoded in software or hardware (or a combination of software and hardware) and operable to communicate with the network (630). More specifically, the interface (604) may include software supporting one or more communication protocols associated with communications such that the network (630) or interface's hardware is operable to communicate physical signals within and outside of the illustrated computer (602).

The computer (602) includes at least one computer processor (605). Although illustrated as a single computer processor (605) in FIG. 6, two or more processors may be used according to particular needs, desires, or particular implementations of the computer (602). Generally, the computer processor (605) executes instructions and manipulates data to perform the operations of the computer (602) and any algorithms, methods, functions, processes, flows, and procedures as described in the instant disclosure. In some embodiments, a computer processor (605) is one or more integrated circuits, one or more microcontrollers, and/or one or more parallel processors. For example, the computer processor may include various circuitry for operating a computer (602) and related-computer devices. Additionally, the computer processor (605) may correspond to a central processing unit (CPU) that is disposed on a printed circuit board in the computer (602).

The computer (602) also includes a memory (606) that holds data for the computer (602) or other components (or a combination of both) that can be connected to the network (630). For example, memory (606) can be a database storing data consistent with this disclosure. Although illustrated as a single memory (606) in FIG. 6, two or more memories may be used according to particular needs, desires, or particular implementations of the computer (602) and the described functionality. While memory (606) is illustrated as an integral component of the computer (602), in alternative implementations, memory (606) can be external to the computer (602).

The application (607) is an algorithmic software engine providing functionality according to particular needs, desires, or particular implementations of the computer (602), particularly with respect to functionality described in this disclosure. For example, application (607) can serve as one or more components, modules, applications, etc. Further, although illustrated as a single application (607), the application (607) may be implemented as multiple applications (607) on the computer (602). In addition, although illustrated as integral to the computer (602), in alternative implementations, the application (607) can be external to the computer (602).

There may be any number of computers (602) associated with, or external to, a computer system containing computer (602), each computer (602) communicating over network (630). Further, the term “client,” “user,” and other appropriate terminology may be used interchangeably as appropriate without departing from the scope of this disclosure. Moreover, this disclosure contemplates that many users may use one computer (602), or that one user may use multiple computers (602).

In some embodiments, the computer (602) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method, comprising:
obtaining first well data and mechanical failure data from a first plurality of wells regarding a first geological region of interest;
determining, by a computer processor, a first stochastic assessment for the first geological region of interest based on the first well data, mechanical failure data, and a stochastic model;
generating, automatically by the computer processor and based on a first screening criterion and the first stochastic assessment, a first reservoir development plan for the first geological region of interest,
wherein the first reservoir development plan comprises a first plurality of production wells based on a first plurality of well operations, and
wherein the first screening criterion removes at least one well operation from inclusion in the first reservoir development plan;
obtaining second well data and second mechanical failure data from the first plurality of wells;
determining, by the computer processor, a second stochastic assessment for the first geological region of interest based on the second well data and the stochastic model;
adjusting, automatically by the computer processor and based on the first screening criterion and the second stochastic assessment, the first reservoir development plan to produce an adjusted reservoir development plan,
wherein the adjusted reservoir development plan comprises a second plurality of production wells that is a subset of the first plurality of production wells based on a second plurality of well operations that is a subset of the first plurality of well operations; and
transmitting, by the computer processor and to a control system coupled to a first well, a command that implements a first well operation among the second plurality of well operations in the adjusted reservoir development plan.

2. The method of claim 1, further comprising:
determining a plurality of hydraulic stimulation operations for an unconventional reservoir based on the second well data and the adjusted reservoir development plan,
wherein the second plurality of well operations comprises the plurality of hydraulic stimulation operations; and
performing, using a second control system and at a second well, a hydraulic stimulation operation among the plurality of hydraulic stimulation operations.

3. The method of claim 1, further comprising:
obtaining historical scheduling data for a plurality of historical well operations; and
determining an amount of schedule variation for a predetermined well operation based on the historical scheduling data,
wherein the first stochastic assessment is based on the amount of schedule variation of the predetermined well operation.

4. The method of claim 1,
wherein the first screening criterion corresponds to a predetermined threshold for a probability of commerciality,
wherein the first screening criterion removes a production well from among the first plurality of production wells in the second plurality of production wells, and
wherein the production well corresponded to a predicted range of hydrocarbon production in the second stochastic assessment that fails to satisfy the predetermined threshold.

5. The method of claim 1, further comprising:
obtaining third well data from a second plurality of wells regarding a second geological region of interest;
determining a third stochastic assessment for a third plurality of production wells in a second reservoir development plan for the second geological region of interest;
obtaining a ranking criterion for the second reservoir development plan;
determining a production well ranking of the third plurality of production wells using the ranking criterion; and
determining the second reservoir development plan based on the production well ranking,
wherein the second reservoir development plan describes a priority that the third plurality of production wells are developed in the second geological region of interest.

6. The method of claim 5,
wherein the ranking criterion corresponds to a probability that a predetermined amount of hydrocarbon that is produced by a respective production well exceeds a cost of developing the respective production well, and
wherein the production well ranking describes a predetermined order that the third plurality of production wells are completed for developing the second geological region of interest.

7. The method of claim 1, further comprising:
obtaining a machine-learning model; and
determining, using the machine-learning model and a portion of the second well data, predicted cost data for a predetermined well operation,
wherein the first screening criterion is a cost threshold, and
wherein the predetermined well operation is excluded from the adjusted reservoir development plan based on the predicted cost data failing to satisfy the cost threshold.

8. The method of claim 1,
wherein the first stochastic assessment is determined using a plurality of Monte Carlo simulations, and
wherein at least one Monte Carlo simulation among the plurality of Monte Carlo simulations describes a plurality of probabilities for a plurality of well scenarios for at least one production well among the first plurality of production wells.

9. The method of claim 1,
wherein the first stochastic assessment comprises:
a first amount of uncertainty at a well's exploratory stage,
a second amount of uncertainty at a well's appraisal stage,
a third amount of uncertainty at a well's pilot stage, and
a fourth amount of uncertainty at a well's production stage.

10. The method of claim 1, further comprising:
obtaining historical cost data for a plurality of historical well operations; and
determining an amount of cost variation of the first plurality of well operations based on the historical cost data,
wherein the first stochastic assessment is based on the amount of cost variation.

11. The method of claim 1, further comprising:
transmitting a second command to a drilling system at a second well from the adjusted reservoir development plan,
wherein the second plurality of production wells in the adjusted reservoir development plan comprises the second well,
wherein the drilling system comprises a second control system coupled to a drill string and a drill bit, and
wherein the drilling system performs a drilling operation that produces a well path through the first geological region of interest in response to receiving the second command.

12. The method of claim 1, further comprising:
presenting, by a user device using a graphical user interface, the adjusted reservoir development plan among a plurality of reservoir development plans; and
obtaining, in response to a user input within the graphical user interface, a user selection of the adjusted reservoir development plan among the plurality of reservoir development plans,
wherein the command is transmitted in response to the user selection.

13. The method of claim 1,
wherein at least one well operation among the first plurality of well operations is selected from a group consisting of:
an injection operation using an injection well,
a drilling operation for a well path for a production well, and a hydraulic stimulation operation for the production well,
a well completion operation for the production well, a well intervention operation for the production well, and
a well maintenance operation for the production well.

14. A system, comprising:
a logging system coupled to a first well;
a drilling system coupled to a second well; and
a reservoir development manager comprising a computer processor, wherein the reservoir development manager is coupled to the logging system and the drilling system, the reservoir development manager being configured to perform a method comprising:
obtaining, using at least in part the logging system, first well data from a first plurality of wells regarding a first geological region of interest, wherein the first plurality of wells comprises the first well;
obtaining mechanical failure data from a plurality of drilling operations at the first plurality of wells;
determining a first stochastic assessment for the first geological region of interest based on the first well data, the mechanical failure data, and a stochastic model;
generating, automatically based on a first screening criterion and the first stochastic assessment, a first reservoir development plan for the first geological region of interest,
wherein the first reservoir development plan comprises a first plurality of production wells based on a first plurality of well operations, and
wherein the first screening criterion removes at least one well operation from inclusion in the first reservoir development plan;
obtaining second well data and second mechanical failure data from the first plurality of wells;
determining a second stochastic assessment for the first geological region of interest based on the second well data and the stochastic model;
adjusting, automatically based on the first screening criterion and the second stochastic assessment, the first reservoir development plan to produce an adjusted reservoir development plan,
wherein the adjusted reservoir development plan comprises a second plurality of production wells that is a subset of the first plurality of production wells based on a second plurality of well operations that is a subset of the first plurality of well operations; and
transmitting, to the drilling system, a command that implements a drilling operation among the second plurality of well operations in the adjusted reservoir development plan.

15. The system of claim 14, further comprising:
a stimulation control system coupled to a third well,
wherein the reservoir development manager is configured to determine a plurality of hydraulic stimulation operations for an unconventional reservoir based on the second well data and the adjusted reservoir development plan,
wherein the second plurality of well operations comprises the plurality of hydraulic stimulation operations; and
wherein the stimulation control system is configured to perform a hydraulic stimulation operation among the plurality of hydraulic stimulation operations.

16. The system of claim 14, wherein the method further comprises:
obtaining historical scheduling data for a plurality of historical well operations; and
determining an amount of schedule variation for a predetermined well operation based on the historical scheduling data,
wherein the first stochastic assessment is based on the amount of schedule variation of the predetermined well operation.

17. The system of claim 14, wherein the method further comprises:
wherein the first screening criterion corresponds to a predetermined threshold for a probability of commerciality,
wherein the first screening criterion removes a production well from among the first plurality of production wells in the second plurality of production wells, and
wherein the production well corresponded to a predicted range of hydrocarbon production in the second stochastic assessment that fails to satisfy the predetermined threshold.

18. The system of claim 14, wherein the method further comprises:
obtaining third well data from a second plurality of wells regarding a second geological region of interest;
determining a third stochastic assessment for a third plurality of production wells in a second reservoir development plan for the second geological region of interest;
obtaining a ranking criterion for the second reservoir development plan;
determining a production well ranking of the third plurality of production wells using the ranking criterion; and
determining the second reservoir development plan based on the production well ranking,
wherein the second reservoir development plan describes a priority that the third plurality of production wells are developed in the second geological region of interest.

19. The system of claim 14, wherein the method further comprises:
obtaining a machine-learning model; and
determining, using the machine-learning model and a portion of the second well data, predicted cost data for a predetermined well operation,
wherein the first screening criterion is a cost threshold, and
wherein the predetermined well operation is excluded from the adjusted reservoir development plan based on the predicted cost data failing to satisfy the cost threshold.

20. The system of claim 14, further comprising:
a downhole sampling device coupled to the first well,
wherein the downhole sampling device is configured to acquire a downhole fluid sample from a wellbore coupled to the first well,
wherein the downhole sampling device comprises a hydraulic fluid chamber, a sample chamber, a floating piston, a mechanical timer, a triggering system, a hanging head, and a closing mechanism, and
wherein the first well data is based on the downhole fluid sample.
